(19) United States
(12) Patent Application Publication
(10) Pub. No.: US 2025/0148162 A1
(43) Pub. Date: May 8, 2025

(54) TECHNIQUES FOR GENERATIVE DESIGN USING MULTI-DISCIPLINARY OPTIMIZATION

(71) Applicant: AUTODESK, INC., San Francisco, CA (US)

(72) Inventors: Hyunmin CHEONG, Toronto (CA); Mehran EBRAHIMI, Toronto (CA); Adrian BUTSCHER, Toronto (CA); Hesam SALEHIPOUR, Richmond Hill (CA)

(21) Appl. No.: 18/821,981

(22) Filed: Aug. 30, 2024

Related U.S. Application Data
(60) Provisional application No. 63/596,922, filed on Nov. 7, 2023.
(60) Provisional application No. 63/606,041, filed on Dec. 4, 2023.

(51) Int. Cl. G06F 30/20

(52) U.S. Cl. CPC G06F 30/20

(57) ABSTRACT

In various embodiments, a generative design application can leverage multi-disciplinary optimization to solve a design problem associated with a 3D model and interdependent design variables. The generative design application includes an optimization engine that can solve the design problem, or portions thereof, by iteratively performing optimization techniques on the interdependent design variables to generate an 3D model that maximizes or minimizes one or more objectives and meets one or more constraints, while simultaneously considering the effect of each interdependency of the design variables. Furthermore, the generative design application can leverage a natural language interface to augment the creation of the design problem for optimization. The generative design application can also leverage free-form deformation during generative design to parameterize a portion of the 3D model as part of the design problem.

### CROSS-REFERENCE TO RELATED APPLICATIONS

This application claims priority benefit of the United States Provisional Patent Application titled “MULTI-VIEW USER INTERFACE FOR SYSTEM-LEVEL GENERATIVE DESIGN,” filed on Nov. 7, 2023, and having Ser. No. 63/596,922, and the United States Provisional Patent Application titled “MULTI-DISCIPLINARY OPTIMIZATION APPROACH TO GENERATIVE ASSEMBLY DESIGN WORKFLOWS,” filed on Dec. 4, 2023, and having Ser. No. 63/606,041. The subject matter of these related applications is hereby incorporated herein by reference.

### BACKGROUND

### Field of the Various Embodiments

The various embodiments relate generally to computer science and complex software and, more specifically, to techniques for generative design using multi-disciplinary optimization.

### Description of the Related Art

Generative design is an algorithm-driven design process, sometimes enhanced by machine learning, where numerous design possibilities are iteratively explored to optimize a given design. Generative design techniques have been implemented in computer-aided design (“CAD”) applications to enable designers to explore design spaces far more effectively and thoroughly than can be accomplished by an individual designer attempting to explore a design space more manually.

One approach for optimizing multiple interrelated components of a system is multi-disciplinary optimization (“MDO”). In MDO, the effects of various design variables, such as physics, components, constraints, and environments, of the system can be simultaneously considered in an optimization problem. When performing multi-disciplinary optimization, designers typically use physics simulation applications to optimize different aspects of a given design.

One drawback to using conventional physics simulation applications, though, is the inability to directly perform simulations using a three-dimensional (“3D”) model from a conventional CAD application in a physics simulation application. To fully simulate a 3D model in a physics simulation application, the designer would need to import the 3D model in the physics simulation application and apply additional operations, such as meshing and setting up boundary conditions. However, doing so is tedious and difficult because the designer is required to switch between two applications, one for 3D modeling and one for physics simulation, which can also lead to suboptimal designs. Additionally, the skill needed to be able to write the program code to apply the additional operations on the 3D model in the physics simulation is unobtainable for the average user. Alternatively, if importing the 3D model is not possible, a designer could recreate an approximation to the 3D model by using internal pre-built components of the physics simulation application. However, due to the limited availability of the pre-built components, it may not be possible to accurately recreate the 3D model. This problem is exacerbated when the 3D model increases in complexity, such as a 3D model of an automobile or airplane. Optimizing an inaccurate model is a waste of time and resources.

Another alternative is to optimize only certain subsystems or components of the overall system. The optimization results can then be used to update the 3D model in the CAD application. However, this approach results in suboptimal designs that do not consider the possible interrelated components of the system, which is also exacerbated by the complexity of the 3D model.

As the foregoing illustrates, what is needed in the art is more effective techniques for performing generative design.

### SUMMARY

One embodiment of the present invention sets forth a computer-implemented method for generating optimized designs, the method comprising: receiving first user input that includes a plurality of interdependent design variables and 3D shape; generating, based on the first user input, a design problem that includes the plurality of interdependent design variables and the 3D shape, wherein the design problem defines one or more associations between the plurality of interdependent design variables and a geometry for the 3D shape; receiving second user input that includes one or more objectives associated with the design problem and one or more constraints associated with the design problem; and iteratively performing, based on the design problem, one or more operations on the plurality of interdependent design variables and the geometry for the 3D shape to generate an updated geometry for the 3D shape.

Other embodiments of the present invention sets forth a computer-implemented method for generating designs using a natural language interface coupled to a language model, the method comprising: receiving natural language input associated with one or more updates to a current design problem that defines one or more associations between a plurality of interdependent design variables and geometry for a 3D shape; sending the natural language input to the language model for processing; receiving, from the language model, a design problem that includes the one or more updates to the current design problem; and iteratively performing, based on the design problem, one or more operations on the plurality of interdependent design variables and the geometry for the 3D shape to generate an updated geometry for the 3D shape.

Other embodiments of the present invention sets forth a computer-implemented method for generating designs using free-form deformation, the method comprising: generating, based on user input, one or more envelope curves located on a first portion of a 3D shape; generating, based on the one or more envelope curves, a free-form deformation box that comprises one or more control points; determining a design problem that includes one or more design variables associated with one or more locations of the one or more control points, wherein the design problem defines one or more associations between the one or more design variables and a geometry for the first portion of the 3D shape; iteratively performing, based on the design problem, one or more operations on the one or more design variables to generate one or more updated envelope curves on the first portion of the 3D shape, wherein the one or more updated envelope curves define an updated geometry for the first portion of the 3D shape.

At least one technical advantage of the disclosed techniques relative to the prior art is that, with the disclosed techniques, a design problem associated with a 3D model and interdependent system components can be specified and solved much faster via a single user interface. The 3D model does not need to be exported to and modified in a separate application prior to solving the design problem. In that regard, the disclosed techniques are not limited by the skill needed to write expert level code for the separate application, nor are the disclosed techniques limited by a closed design space of pre-built components. As a result, the likelihood that the 3D model is accurately optimized to meet user objectives is increased.

Another technical advantage of the disclosed techniques relative to the prior art is that, with the disclosed techniques, a design problem associated with a 3D model and interdependent system components can be specified and solved more accurately using natural language user inputs. Although design problems with interdependent design variables are more complex, using trained language models and a natural language interface to augment the creation of a design problem enables a MDO generative design application to explore the design space in a more directed and therefore accurate fashion. As a result, the likelihood that the 3D model is accurately optimized to meet user objectives is increased.

Another technical advantage of the disclosed techniques relative to the prior art is that, with the disclosed techniques, a design problem associated with a 3D model can be solved with more control over a portion of the geometry of the 3D model. By focusing the design problem on a portion of the 3D model instead of the entirety of the 3D model, solutions that offer limited modifications to only the portion of the 3D model, while preserving the overall geometry of the 3D model, can be efficiently found. As a result, the likelihood that the 3D model is accurately optimized to meet user objectives is increased.

These technical advantages provide one or more technological improvements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a system configured to implement one or more aspects of the various embodiments;

FIG. 2 is a more detailed illustration of the graphical user interface of FIG. 1, according to various embodiments;

FIG. 3 sets forth a flow diagram of method steps for generating a design of a system having interdependent design variables, according to various embodiments;

FIG. 4 is a more detailed illustration of the language model and design problem engine of FIG. 1, according to various embodiments;

FIG. 5 sets forth a flow diagram of method steps for generating a design using a language model, according to various embodiments;

FIG. 6 is more detailed illustration of the free-form deformation module of FIG. 1, according to various embodiments;

FIG. 7 is a more detailed illustration of the optimization engine of FIG. 1, according to various embodiments;

FIG. 8 illustrates an exemplar user interface for creating free-form deformation boxes, according to various embodiments;

FIG. 9 sets forth a flow diagram of method steps for generating a design using a free-form deformation box, according to various embodiments; and

FIG. 10 sets forth another more detailed flow diagram for executing optimization techniques to generate an updated 3D model, according to various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

### System Overview

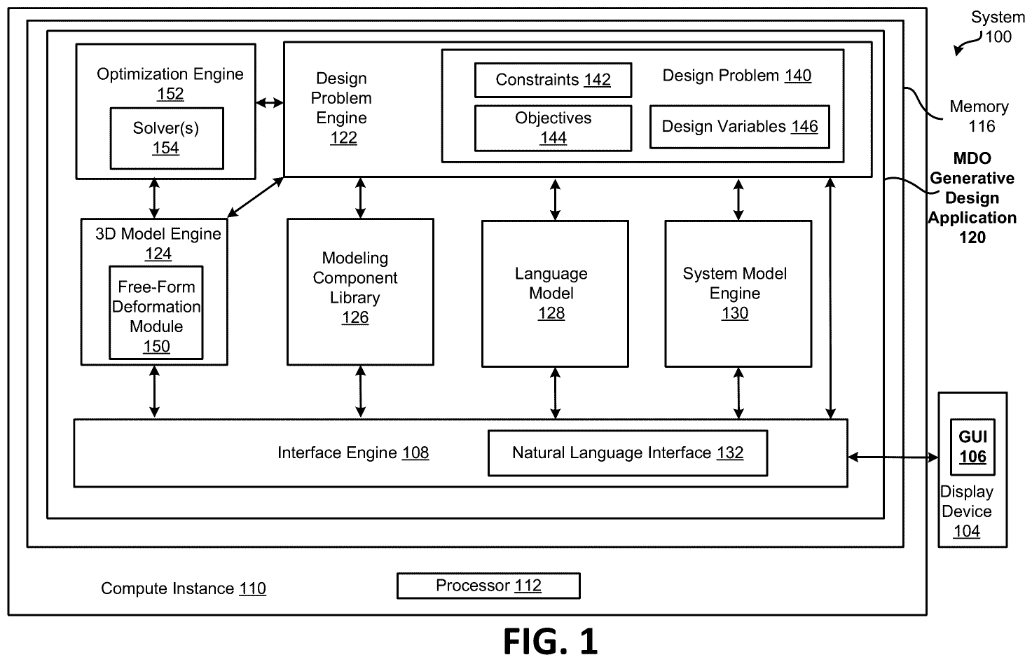

FIG. 1 is a conceptual illustration of a system 100 configured to implement one or more aspects of the various embodiments. As shown, the system 100 includes, without limitation, a display device 104 and a compute instance 110.

As shown, the compute instance 110 includes, without limitation, a processor 112 and a memory 116. The processor 112 can be any instruction execution system, apparatus, or device capable of executing instructions. For example, the processor 112 could include a central processing unit, a graphics processing unit, a controller, a micro-controller, a state machine, or any combination thereof. The memory 116 stores content, such as software applications and data, for use by the processor 112. In some alternate embodiments, each of any number of instances of the compute instance 110 can include any number of instances of the processor 112 and any number of instances of the memory 116 in any combination. In particular, any number of instances of the compute instance 110 (including one) can provide a multiprocessing environment in any technically feasible fashion.

The memory 116 can be one or more of a readily available memory, such as random-access memory, read only memory, floppy disk, hard disk, or any other form of digital storage, local or remote. In some embodiments, a storage (not shown) can supplement or replace the memory 116. The storage can include any number and type of external memories that are accessible to the processor 112. For example, and without limitation, the storage can include a Secure Digital Card, an external Flash memory, a portable compact disc read-only memory, an optical storage device, a magnetic storage device, or any suitable combination of the foregoing.

The compute instances 110 is configured to implement one or more software applications. For explanatory purposes only, each software application is described as residing in the memory 116 of the compute instance 110 and executing on the processor 112 of the compute instance 110. However, in some embodiments, the functionality of any number of software applications can be distributed across any number of other software applications that reside in instances of the memory 116 of any number of instances of the compute instance 110 and execute on any number of instances of the processor 112 of any number of instances of the compute instance 110 in any combination. Further, the functionality of any number of software applications can be consolidated into a single software application.

As shown, the computer instance 110 is configured to execute a multi-disciplinary optimization (“MDO”) generative design application 120, that implements generative design techniques to solve design problems of a 3D model in a system based on any number and/or type of design objectives, any and/or types of design constraints, and any and/or types of design variables. As described previously herein, generative design is an algorithm-driven design process, sometimes enhanced by machine learning, where numerous design possibilities are iteratively explored to optimize a given design. Generative design techniques enable designers to explore design spaces more effectively and thoroughly than can be accomplished by an individual designer attempting to explore a design space more manually. However, conventional approaches to generative design cannot optimize a system with multiple interrelated components.

The MDO generative design application 120 resides in the memory 116 of the compute instance 110 and executes on the processor 112 of the compute instance 110. More generally, the functionality of the MDO generative design application 120 can be distributed across any number of software applications. Each of the software applications can reside in any number of instances of the memory 116 of any number of instances of the compute instances 110 and execute on any number of instances of the processor 112 of any number of instances of the compute instances 110 in any combination. For explanatory purposes, multiple instances of like objects are denoted with reference numbers identifying the object and parenthetical alphanumeric character(s) identifying the instance where needed.

Any number of the components of the system 100 can be distributed across multiple geographic locations or implemented in one or more cloud computing environments (i.e., encapsulated shared resources, software, data, etc.) in any combination. In some embodiments, the system 100 can include, without limitation, any number (including zero) of instances of the display device 104 and any number of instances of the compute instance 110. In the same or other embodiments, each instance of the compute instance 110 can be implemented in a cloud computing environment, implemented as part of any other distributed computing environment, or implemented in a stand-alone fashion.

As shown, in some embodiments, the compute instance 110 is associated with the display device 104. The display device 104 can be any device that is capable of displaying an image and/or any other type of visual content. For example, the display device 104 could be, without limitation, a liquid crystal display, a light-emitting diode display, a projection display, a plasma display panel, etc. In some embodiments, the display device 104 is a touchscreen that is capable of displaying visual content and receiving input (e.g., from a user).

In some embodiments, the compute instance 110 can be integrated with any number and/or types of other devices (e.g., other instances of the compute instance 110, input devices, output devices, input/output devices, etc.) into a user device. Some examples of user devices include, without limitation, desktop computers, laptops, smartphones, smart televisions, game consoles, tablets, etc.

One approach for optimizing multiple interrelated components of a system is MDO. In MDO, the effects of various design variables, such as physics, components, constraints, and environments, of the system can be simultaneously considered in an optimization problem. When performing multi-disciplinary optimization, designers typically use system-modeling tools, such as physics simulation applications, to optimize different aspects of a given design.

One drawback to using conventional physics simulation applications, though, is the inability to directly perform simulations using a three-dimensional (“3D”) model from a conventional CAD application in a physics simulation application. To fully simulate a 3D model in a physics simulation application, the designer would need to import the 3D model in the physics simulation application and apply additional operations, such as meshing and setting up boundary conditions. However, doing so is tedious and difficult because the designer is required to switch between two applications, one for 3D modeling and one for physics simulation, which can also lead to suboptimal designs. Additionally, the skill needed to be able to write the program code to apply the additional operations on the 3D model in the physics simulation is unobtainable for the average user. Alternatively, if importing the 3D model is not possible, a designer could recreate an approximation to the 3D model by using internal pre-built components of the physics simulation application. However, due to the limited availability of the pre-built components, it may not be possible to accurately recreate the 3D model. This problem is exacerbated when the 3D model increases in complexity, such as a 3D model of an automobile or airplane. Optimizing an inaccurate model is a waste of time and resources. Another alternative is to optimize only certain subsystems or design variables of the overall system. The optimization results can then be used to update the 3D model in the CAD application. However, this approach results in suboptimal designs that do not consider the possible interrelated design variables of the system, which is also exacerbated by the complexity of the 3D model.

### Multi-View User Interface for MDO Generative Design

To address the above problems, in some embodiments, the MDO generative design application 120 is a computer-aided design (“CAD”) application that implements MDO generative design techniques to generate and solve design problems based on any number and/or type of design objectives, any and/or types of design constraints and any and/or types of design variables. A design objective can be the goal of optimization, such as maximizing fuel efficiency of a 3D model. A constraint can be a restriction or requirement that the design problem must adhere to during optimization, such as adherence to various criteria in a standard. Design variables can include physics modeling components, modeling components, and environment modeling components that are interdependent with other design variables and/or parts of the system. In some embodiments, design variables can be interdependent with a 3D model and/or other design variable(s) of the system. The interdependency of a design variable can include a two-way coupling between the design variable and the 3D model or other design variable(s) of the system such that an output associated with computing the design variable can be used as the input to determine the 3D model or other design variable. For example, a design problem to find optimal blade dimensions of an airplane wing can have multiple interdependent design variables, such as aerodynamics and structural mechanics of a 3D model of the airplane wing. When computing the aerodynamics of the 3D model, the output value of the force computed can be used in the structural mechanics computation to determine an accurate displacement value for the wing, which in turn is input into the aerodynamics computation to determine an accurate value of the force. These values of force and displacement may never converge regardless of the number of computations performed for each physics modeling component associated with the respective interdependent design variable. To solve this design problem, the MDO generative design application 120 can simultaneously compute the design variables during optimization to find a converged state in which the two-way coupling does not produce a feedback loop.

As shown in FIG. 1, in some embodiments, the MDO generative design application 120 includes, without limitation, an optimization engine 152, a problem definition engine 122, a 3D model engine 124, a modeling component library 126, a language model 128, a system model engine 130, and an interface engine 108.

In some embodiments, the 3D model engine 124 generates a 3D model that includes a virtual object with geometry of a 3D shape that includes the same properties as a physical object including, but not limited to textures, material, weight, size, optical properties, and/or physical properties. In some embodiments, the 3D model engine 124 receives any number and/or types of inputs via the interface engine 108 to facilitate the generation of the 3D model. As shown, the 3D model engine 124 includes a free-form deformation module 150 that can parameterize the geometry of a portion of a 3D model via a free-form deformation box. In some embodiments, the 3D model engine 124 can render the 3D model for display to a user, in any technically feasible fashion. In some embodiments, the 3D model engine 124 sends the 3D model or data representing the 3D model to the interface engine 108 for rendering and output via the GUI 106. In some embodiments, the 3D model engine 124 sends data representing the 3D model to the design problem engine 122 to generate a design problem, such as design problem 140. The design problem engine 122 can use the data representing the 3D model in conjunction with other data received from one or more other modeling engines, and/or libraries, such as the system model engine 130 and the modeling component library 126, to generate the design problem 140. In some embodiments, the data representing the 3D model can be formatted as a conventional CAD file, or any other compatible format. In some embodiments, semantic information associated with the 3D model, such as a file name and/or labels of parts of the 3d model, are included in the data representing the 3D model. In some embodiments, the 3D model engine 124 can receive data representing updates to the 3D model from the optimization engine 152 or any other part of the MDO generative design application 120. The 3D model engine 124 can update the 3D model based on the data representing updates to the 3D model. In some embodiments, the 3D model engine 124 can render the updated 3D model in any technically feasible fashion. In some embodiments, the 3D model engine 124 sends the updated 3D model to the interface engine 108 for output via the GUI 106. In some embodiments, the 3D model engine 124 sends data representing the updated 3D model to the design problem engine 122 to generate an updated design problem, such as design problem 140.

In some embodiments, the system model engine 130 generates a system model that includes at least a portion of a 3D model generated by the 3D model engine 124, interdependent design variables associated with the 3D model or portion(s) thereof, and the interdependent relationship of the design variables. In some embodiments, the interdependent design variables include modeling components from the modeling component library 126, discussed in greater detail below. In some embodiments, the system model engine 130 receives any number and/or types of inputs via the interface engine 108 to facilitate the generation of the system model, including at least the portion of the 3D model and the interdependent design variables and the interdependent relationships of the design variables. In some embodiments the system model 130 sends the system model or data representing the system model to the interface engine 108 for output via the GUI 106. In some embodiments, the system model engine 130 sends data representing the system model to the design problem engine 122, which uses the data representing the system model in conjunction with other data received from one or more other modeling engines, and/or libraries, to generate a design problem, such as design problem 140, as described above. In some embodiments, the data representing the system model can be formatted using a system model language, such as the systems modeling language (“SysML”) or the unified modeling language (“UML”), or any other compatible format. In some embodiments, semantic information associated with the system model, such as a file name and/or labels of parts of the system model, are included in the data representing the system model. In some embodiments, the system model engine 130 can receive data representing updates to the system model from the design problem engine 122, the interface engine 108, the optimization engine 152, and/or any other part of the MDO generative design application 120. The system model engine 130 can update the system model based on the data representing updates to the system model. In some embodiments, the system model engine 130 sends the updated system model to the interface engine 108 for output via the GUI 106. In some embodiments, the system model engine 130 sends data representing the updated system model to the design problem engine 122 to generate an updated design problem, such as design problem 140.

In some embodiments, the modeling component library 126 is a library of data representing various modeling components, such as environment definitions, physics definitions, system modeling components, and/or design requirements that can be used by the MDO generative design application 120 to generate a system model and a design problem. In some embodiments, the modeling component library 126 can include, without limitation, modeling components imported from a CAD application, modeling components generated by the MDO generative design application 120, modeling components generated based on user input, and/or any other compatible modeling components. The modeling components can be any technically feasible components that can be included/added to the system model to represent a system associated with a 3D model. For example, the library of data could include any number and/or types of modeling components for a system model to represent a system associated with a 3D model generated by the 3D model engine, including but not limited to, physics modeling components, system modeling components, environment modeling components, constraints, and/or objectives. In some embodiments, the modeling component library 126 can recommend and send various modeling components or data representing the modeling components to the interface engine 108 for output via the GUI 106. In some embodiments, the recommendation is based on the 3D model, the system model, other modeling components, or other aspects associated with the 3D model. For example, components of an automobile could be recommended for a 3D model of an automobile. In some embodiments, the modeling component library 126 sends data representing one or more modeling components to the design problem engine 122, which uses the data representing the modeling components in conjunction with other data, to generate a design problem, such as design problem 140, as described above. For example, one or more modeling components could be used as design variables 146, constraints 142, and/or objectives 144, in design problem 140. In some embodiments, the data representing the one or more modeling components can be formatted using any formal language, such as the extensive markup language (“XML”), JavaScript Object Notation (“JSON”), or resource description framework in attributes (“RDF”), or any other compatible format. In some embodiments, semantic information associated with the one or more model components, such as a file name or labels, are included in the data representing the one or more modeling components.

In some embodiments, the MDO generative design application 120 generates, in any technically feasible fashion, a design problem, such as design problem 140, via the design problem engine 122. The design problem 140 describes the overall optimization problem for optimizing a design and specifies, without limitation, any amount and/or types of ancillary data. As shown, the design problem 140 includes, at least, objectives 144, constraints 142, and design variables 146. In some embodiments, data representing the design problem 140 can be formatted using any formal language, such as XML, JSON, or RDF, or any other compatible format. In some embodiments, semantic information associated with the design problem 140, such as a file name or labels, are included in the data representing the design problem 140. The design problem engine 122 can receive data indicating updates associated with one or more parts of the design problem 140 from any of the engines, libraries, models, or other aspects of the MDO generative design application 120, including user input via the GUI 106. The design problem engine 122 can send the data indicating updates to the respective engines, libraries, models, or other aspects of the MDO generative application 120 to incorporate the updates. For example, the design problem engine 120 could receive data from the language model 128 indicating that a parameter associated with a modeling component from the modeling component library 126 has been selected by a user to be a design variable, such as one of the design variables 146, of the design problem 140. In turn, the design problem engine 140 can update the design problem 140 to incorporate the selected parameter associated with the modeling component as a part of the design variables 146, and the system model engine 130 can also incorporate the modeling component as part of the system model.

The objectives 144 are any amount and/or types of design objectives or optimization goals to be achieved during optimization. In some embodiments, the objectives 144 can be included in one or more objective functions to be maximized or minimized, as discussed in greater detail below. For example, maximizing the value of an objective function could result in a design that best meets the objectives 144. For instance, in some embodiments, the objectives 144 include, without limitation, any number of design objectives or optimization goals that are specified at a high level by a user (e.g., via the GUI 106), any number of design objectives or optimization goals derived based on any other types of user input, and/or any number and/or types of design objectives or optimization goals associated with any aspect(s) of the 3D model. Some examples of design objectives include, without limitation, maximizing fuel efficiency, maximizing performance, maximizing comfort, minimizing embodied carbon, minimizing material cost, and minimizing material waste, to name a few.

The constraints 142 can specify any amount and/or types of constraints, restrictions, or requirements associated with designing the 3D model. For instance, in some embodiments, the constraints 132 include, without limitation, any number of design constraints that are specified at a high level by a user (e.g., via the GUI 106), any number of restrictions derived based on the design constraints and/or any other types of user input, and/or any number and/or types of restrictions associated with any aspect(s) of the 3D model, system model, or the design problem 140. Some examples of design constraints, restrictions, or requirements, include, without limitation, conforming to a safety standard or other regulations, weight requirements, material requirements, and size requirements, to name a few.

The design variables 146 can include any amount and/or type of parameters that are relevant to the designing of a system represented by a 3D model. For instance, the design variables 146 can include any number and/or types of parameters associated with modeling components, such as the modeling components from the modeling component library, that are included in a system. The design variables 146 can also include parameters associated with components of the 3D model and/or the associations between modeling components. The design variables 146 define, at least in part, the design space of the system represented by the 3D model as part of the design problem 140. The design variables 146 can have interdependent relationships with a part of or the entirety of the 3D model or other design variables of the design variables 146. For example, a design variable of the design variables 146 can specify the stiffness of a suspension modeling component associated with the 3D model. The stiffness of the suspension modeling component can be interdependent with design variables associated with a tire modeling component and/or the body shape of a 3D model of an automobile. In some embodiments, the design variables 146 can include parameters associated with a free-form deformation box, such as the locations of one or more control points associated with the free-form deformation box.

The design problem 140, and any parts thereof, can be generated using inputs from any or all of the 3D model engine 124, the modeling component library 126, the language model 128, the system model 130, and the interface engine 108. The design problem engine 122 can generate the design problem 140 in any technically feasible fashion based on any amount and/or type of input data from the GUI 106 via the interface engine 108. As shown, in some embodiments, the design problem engine 122 generates the design problem 140 based, at least in part, on input received from the GUI 106 via the interface engine 108. In the same or other embodiments, the interface engine 108 can display a portion (including none or all) of the design problem 140 via the GUI 106.

As shown, the MDO generative design application 120 also includes the optimization engine 152. In some embodiments, the optimization engine 152 can employ one or more optimization techniques to solve design problems, such as design problem 140 with interdependent design variables, such as design variables 146, that are defined by the design problems. The optimization engine 152 includes one or more solvers 154. In some embodiments, the solver(s) 154 can include, without limitation, a multi-disciplinary analysis solver, an adjoint solver, a physics solver, and/or any other solver(s) needed to solve a given design problem, such as design problem 140, or portions thereof. The optimization engine 152 can consider various design variables data 146, whether the design variables are various physics, environments, and/or modeling components, and simultaneously consider the interdependent relationships of the design variables 146 with respect to other aspects of the design problem 140.

In some embodiments, the design problem engine 122 can generate an objective function of the design problem 140 in any technically feasible fashion, according to the objectives 144. In some embodiments, the objective function quantifies degrees of convergence of designs associated with the design problem or any portions thereof with the objectives 144, given the constraints 142. The objective function can be expressed in any technically feasible fashion. In some embodiments the objective function is a composite function. In the same or other embodiments, the objective function is an aggregation of metrics that are each associated with one or more objectives 144. The design problem engine 122 can send the objective function or data representing the objective function to the optimization engine 152 for use in conjunction with the one or more optimization techniques.

In some embodiments, the optimization engine 152 iteratively employs, without limitation, a gradient-based optimization algorithm to efficiently solve the design problem 140. In some embodiments, the optimization engine 152 can employ gradient-free algorithms, such as evolutionary algorithms to solve the design problem. To find the optimal solution to the design problem, the optimization algorithm can compute the total derivatives of the objective function with respect to the design variables data 146 to update the values of the design variables data 146 at each iteration of optimization. The total derivatives can be computed as follows based on algorithm 1 below,

$$\frac{df}{dx} = \frac{\partial f}{\partial x} + \frac{\partial f}{\partial u} \frac{du}{dx} , \qquad ( 1 )$$

where

$$\frac{d f}{d x}$$

total derivatives of the objective function f with respect to the design variables x. The value of x can affect the value of f via the value of state variables u, which are the physical quantities of interest computed in each of the components of the system model to analyze the behavior of these components. Furthermore, a chain rule can be applied to compute the total derivatives using the partial derivatives, where

$$\frac{\partial f}{\partial x} ,$$

is the partial derivative of f with respect to the design variables x,

$$\frac{\partial f}{\partial u} ,$$

is the partial derivative of the state variables u, and

$$\frac{du}{dx} ,$$

is the derivative of the state variables with respect to the design variables, at each iteration. After each iteration, the optimization engine 152 updates the values of the design variables data 146 based on the total derivatives of the objective function and determines the value of the objective function.

Values of the objective function are also referred to herein collectively as “objective values” and individually as an “objective value.” In some embodiments, the goal of the optimization engine 152 is to maximize the objective values. In some other embodiments, the goal of the optimization engine 152 is to minimize the objective values. In some embodiments, the optimization engine 152 incorporates any number and/or type of the constraints 142 into the objective values as penalties in any technically feasible fashion. In the same or other embodiments, any number of penalties are disregarded during different optimization operations depending on the design variables 146. The optimization engine 152 continues to iteratively employ the optimization algorithm until the objective values match the goal of the optimization engine 152 or stop improving while incorporating any penalties based on the constraints 142. The objective values that meet the goal while incorporating any penalties correspond to the optimal solution of the design problem 140. During optimization, one or more design variables of the design variables 146 can change to reflect the optimal solution of the design problem 140. For example, if the design problem 140 is associated with a free-form deformation box, the design variables 146 can include one or more locations of one or more control points of the free-form deformation box. The optimization techniques disclosed herein, can change or update the one or more locations of the one or more control points to change the geometry for at least a portion of the 3D model to meet the objectives 144 and constraints 142, The optimization engine 152 can send updates based on the changes in the design variables 146 to the 3D model engine 124 to update the 3D model to the reflect the changes made during optimization. In the free-form deformation box example, the 3D model engine 124 can update the geometry for the portion of the 3D model based on the changes/updates to the design variables 146, which in this example would be the updated one or more locations of the one or more control points. In some embodiments, the 3D model engine 124 can send the updated 3D model to the interface engine 108 for display via the GUI 106.

In some embodiments, the 3D model engine 124 includes a free-form deformation module 150. The free-form deformation module 150 generates a set of envelope curves along a portion of the 3D model. The generation of the set of envelope of curves can be based on any number and/or types of input received from the GUI 106, via the interface engine 108. In some embodiments, the input is based on a user created sketch of envelope curves along the 3D model. The set of envelope curves define the geometry of the 3D model that will change during optimization. Once the set of envelope curves is created, the free-form deformation module 150 creates a free-form deformation box that encompasses the set of envelope curves, which can be represented as a 3D box over of the portion of the 3D model. In some embodiments, the free-form deformation box is modeled using B-spline functions, but other compatible modeling functions can also be used. A set of control points can be created along each direction of the free-form deformation box. A change in the location of the one or more control points corresponds to a change in the location of the set of envelope curves and thereby the geometry of the 3D model. Once the control points are created, the free-form deformation module can send the free-form deformation box, the set of control points, and one or more objectives, such as objectives 144, to the optimization engine 152. The set of control points can be used by the design problem engine 122 as inputs for the design variables data 146 of the design problem 140.

Once the design problem 140 for free-form deformation is generated, the optimization engine 152 can then solve the design problem 140 by performing one or more iterative optimization techniques, such as one or more known optimization algorithms, on the design problem 140, where the objective function f is used to find the optimal locations of the one or more control points based on the objectives 144 and constraints 142. In some embodiments, the optimization engine 152 can simultaneously compute a first derivative indicating a sensitivity, denoted as

$$\frac{\partial s}{\partial c} ,$$

associated with a change in the geometry of the 3D model with respect to a change in one or more locations of the one or more control points and a second derivative indicating a sensitivity, denoted as

$$\frac{\partial f}{\partial s} ,$$

associated with a change in the objective function with respect to the change in the geometry of the 3D model. Using the two sensitivities, the optimization engine 152 can compute a third derivative indicating a sensitivity, denoted as

$$\frac{\partial f}{\partial c} ,$$

associated with a change in the objective function with respect to the change in one or more locations of the control points. The third derivative can then be used to find the optimal locations of the one or more control points. The optimization engine 152 can send the optimal locations to the free-form deformation module 150 to change the current locations of the one or more control points to the optimal locations of the one or more control points. By doing so, the free-form deformation module 150 can update the 3D model by using the optimal locations of the one or more control points to change the location of the corresponding set of envelope curves to reflect an optimized geometry of the 3D model. In some embodiments, the free-form deformation module 150 can send the updated 3D model to the interface engine 108 for display via the GUI 106.

In some embodiments, the interface engine 108 displays the GUI 106 via the display device 104. The interface engine 108 can receive any number and/or types of inputs via the GUI 106 and can display any number and/or types of outputs via the GUI 106. In some embodiments, the interface engine 108 receives any number and/or types of design constraints, such as constraints 146, and/or any number and/or types of design objectives, such as objectives 144, via the GUI 106. In the same or other embodiments, the interface engine 108 displays the design problem 140, a portion (including none or all) of any number of solutions of the design problem 140, any number of 3D models, such as those generated by the 3D model engine 124, associated with the design problem 140, any number of system models, such as those generated by the system model engine 130, associated with the design problem 140, any number of design variables, such as design variables 146, any number of system components, and/or any number of current instances of the design problem 140 via the GUI 106.

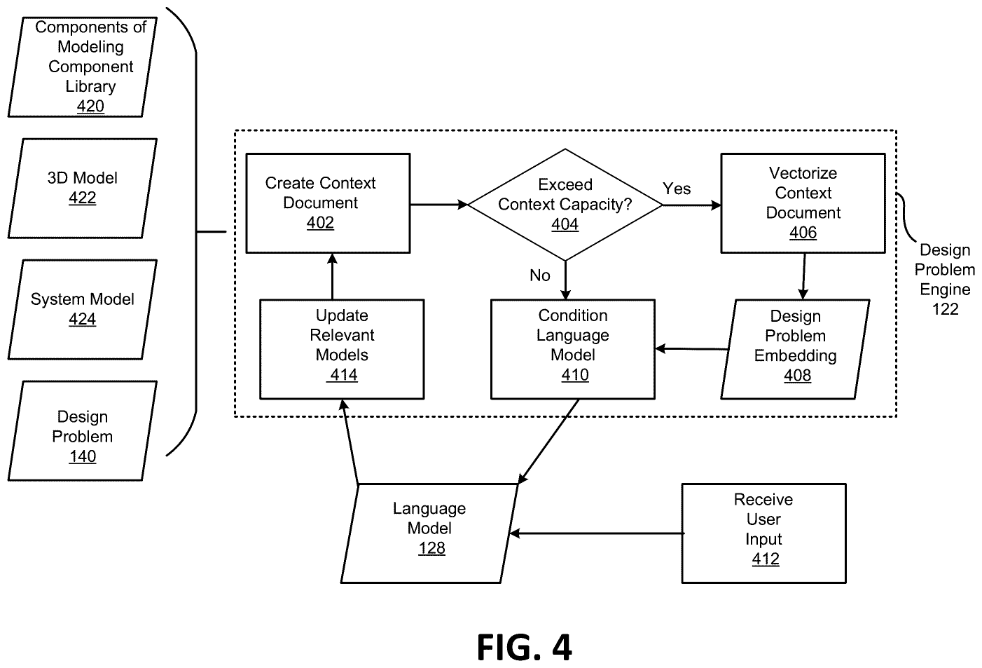

As shown, the interface engine 108 generates a natural language interface 132. The natural language interface 132 can be enabled by the language model 128. In some embodiments, the language model 128 can be a conventional language model that is compatible with the MDO generative design application 120. In some embodiments, the language model 128 can be a version of a conventional language model that is fine tuned to be compatible with the MDO generative design application 120. In some embodiments, the language model 128 can be any type or size language model, such as a large language model or a small language model, that is compatible with the MDO generative design application 120. The language model 128 can be part of the MDO generative design application 120 or external to the MDO generative design application 120, such as a language model that is executing in a cloud computing environment and is accessible via an application programming interface (“API”). The language model 128 can be conditioned with the design problem 140 using context data. For example, the language model 128 could receive data specifying the design problem 140 as context data. If the data constituting the design problem 140 is greater than a pre-determined threshold size that the language model 128 can take as input, the data can be condensed into an embedding via a vectorizer, which can be an embedding model in some embodiments. In some embodiments, the vectorizer can be internal to the MDO generative design application 120. In some embodiments the vectorizer can be external to the MDO generative design application 120. In some embodiments, multiple vectorizers can be used to generate embeddings of different portions of the design problem 140. In some embodiments, the data representing the 3D model can be separately condensed into an embedding via the vectorizer. In some embodiments, the data representing the system model can be separately condensed into an embedding via the vectorizer. In some embodiments, the data representing one or more modeling components of the modeling library can be separately condensed into embeddings via the vectorizer. In some embodiments, the data representing the design problem 140 can be separately condensed into an embedding via the vectorizer. In some embodiments, the user input, such as natural language input, can be condensed into an embedding via the vectorizer. In addition, the language model 128 can receive natural language input from the user to process. In some embodiments, the user input can be used to generate a prompt that includes the natural language user input. The prompt and context data that is obtained via a vector search using the embeddings can then be input into the language model 128, as discussed in greater detail below in conjunction with FIG. 4. The language model 128 can update the data specifying the design problem 140 or a portion thereof to reflect the natural language input. In some embodiments, the design problem engine 122 can validate that any updates output by the language model 128 satisfy one or more predefined schemas for data models associated with the design problem 140, system model, or any other models. If the design problem engine 122 cannot validate the updates, the design problem engine 122 can ask the language model 128 to process the natural language input again while correcting the validation error, thereby generating new updates to the data specifying the design problem 140. The foregoing process can repeat until the updates are validated or a pre-determined threshold of validation attempts have occurred. If the pre-determined threshold of validation attempts have occurred, the language model 128 can send a failure message to the natural language interface 132 for output to the GUI 106. The language model 128 can send data specifying the updates to the design problem 140 to the design problem engine 122 to update any part and/or the entirety of the design problem 140. The above steps can be used in relation to any model or library disclosed herein. For example, if the natural language input indicates that a modeling component of the modeling component library 126 should be included in the system model associated with the 3D model, the language model 128 could update the data specifying the system model based on the natural language input instead. The language model 128 would then send data specifying updates to the system model to the system model engine 130 to update any part and/or the entirety of the system model.

The natural language interface 132 allows the interface engine 108 to receive natural language text from a user in a conversational manner via the GUI 106. In some embodiments, the natural language text includes, but is not limited to, semantic information associated with objectives 144, system components, constraints 142, and/or other design variables, such as design variables 146, associated with the design problem 140, instructions to instantiate system components or design variables 146, instructions to associate portions of the 3D model with system components, and/or other information associated with the design problem 140, the system model, or portion thereof. In some embodiments, the design problem 140, the constraints 142, the objectives 144, and the design variables 146 can be defined, in whole or in part, by natural language text received via the natural language interface. The interface engine 108 can prompt the language model 128 to update the objectives 144, system components, constraints 142, etc. according to the natural language text. During processing, the language model can update the design problem 140, the system model, the 3D model, etc. based on the techniques described above and below. In some embodiments, the interface engine 108 can receive, from the language model 128, data indicating to update any part and/or the entirety of the 3D model, the system model, the design variables 146, and/or the design problem 140. The interface engine 108 can send the data indicating to update any part and/or the entirety of the 3D model, the system model, the design variables 146, and/or the design problem 140 to the design problem engine 122. The natural language interface 132 allows easy interactions of a user with the MDO generative design application 120 and reduces complexity when creating the design problem 140.

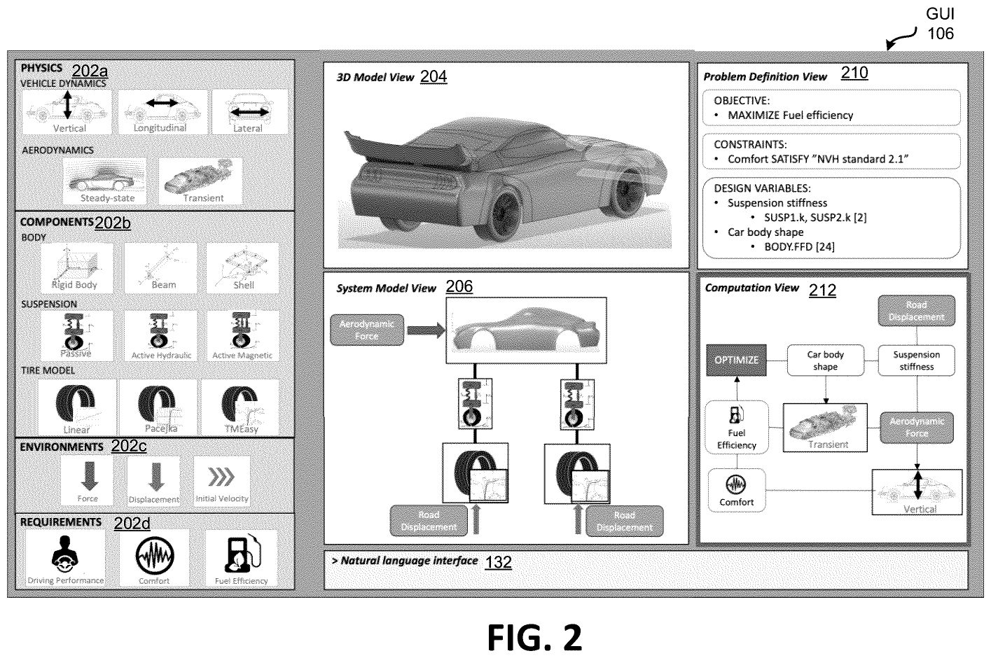

FIG. 2 is a conceptual illustration of the GUI 106, according to various embodiments. As shown, the GUI 106 includes, without limitation, any number of interfaces, such as component menu interfaces 202a-202d, 3D model view 204, system model view 206, natural language interface 208, problem definition view 210, and computation view 212. Component menu interfaces 202a-202d, 3D model view 204, system model view 206, natural language interface 208, problem definition view 210, and computation view 212 form different sections of GUI 106. For explanatory purposes, multiple instances of like objects are denoted with reference numbers identifying the object and parenthetical alphanumeric character(s) identifying the instance where needed.

Any number of the interfaces or components of the GUI 106 can be distributed and arranged across one or more graphical user interfaces in any combination. The arrangement of the interfaces of GUI 106 in FIG. 2 is for exemplary purposes only. In some embodiments, the GUI 106 can be output by a display device, such as the display device 104 in FIG. 1, based on any number of compute instances, such as compute instance 110 in FIG. 1, associated with the system 100 in FIG. 1. In some embodiments, the GUI 106 can be output by an interface engine, such as interface engine 108 in FIG. 1, associated with an application, such as MDO generative design application 120 in FIG. 1, based on data from one or more aspects of the application.

In some embodiments, certain interfaces can be populated or displayed before others, but is not limited to a specific order in which the interfaces of GUI 106 must be populated. The following is an exemplary order in which the interfaces of GUI 106 can be populated.

In some embodiments, the 3D model view 204 is an interface of the GUI 106 for displaying a rendered 3D model. The GUI 106 can receive data associated with a 3D model rendering and display the 3D model in any technically feasible interface, such as the 3D model view 204. The 3D model view 204 can be populated by a 3D model rendered by a 3D model engine, such as 3D model engine 124 in FIG. 1, of an application, such as MDO generative design application 120 in FIG. 1. In some embodiments, the 3D model is associated with a design problem to be solved by the MDO generative design application 120. The 3D model can be any 3D model that represents a virtual object with geometry of a 3D shape that includes the same properties as a physical object including, but not limited to textures, material, weight, size, optical properties, and/or physical properties. For example, FIG. 2 shows a rendered 3D model of an automobile displayed in the 3D model view 204. The 3D model can from a CAD application. Once displayed, the 3D model can be interacted with by a user of the GUI 106. In some embodiments, a user can interact any number of times with the 3D model in any number of ways including, without limitation, editing the 3D model, deleting the 3D model, importing a new 3D model, rotating the 3D model, and/or other similar interactions. Any changes to the 3D model displayed on the 3D model view 204 can be sent to the 3D model engine 124 via the interface engine 108 of the MDO generative design application 120.

In some embodiments, the component menu interfaces 202a-d are part of a selection menu interface of the GUI 106 for displaying various modeling components associated with a modeling library, such as modeling component library 126. The GUI 106 can receive data associated with one or more modeling components and display the modeling components in any technically feasible interface, such as component menu interfaces 202a-d. The component menu interfaces 202a-d can be populated by modeling components associated with a 3D model or system model, such as the modeling components of modeling component library 126 in FIG. 1, based on recommendations from one or more aspects of an application, such as MDO generative design application 120. In some embodiments, the various modeling components are associated with a design problem to be solved by the MDO generative design application 120. The component menu interfaces 202a-d can be displayed in any order for any reason.

For example, FIG. 2 shows a physics menu displayed in component menu interface 202a, a components menu displayed in component menu interface 202b, an environments menu in component menu interface 202c, and a requirements menu in component menu interface 202d. The physics menu displayed in component menu 202a can be populated based on physics modeling components associated with a 3D model, such as the 3D model displayed in the 3D model view 204. For example, in FIG. 2, component menu interface 202a shows various vehicle dynamic and aerodynamic physics that are associated with the 3D model of the automobile displayed on the 3D model view 204. In some embodiments, these physics are recommended based on the relevancy to the 3D model or a natural language input.

The components menu in component menu 202b can be populated based on system modeling components associated with a 3D model, such as the 3D model displayed in the 3D model view 204. For example, in FIG. 2, component menu interface 202b shows various body, suspension, and tire system modeling components that are associated with the 3D model of the automobile displayed on the 3D model view 204. In some embodiments, the system modeling components are recommended based on the user selection of physics. In some embodiments, the system modeling components include mathematical models that compute how the system modeling components contributes to the overall behavior of the system. For example, a user can generate a system modeling component by associating a system modeling component in the component menu 202b with a particular portion of the 3D model, such as the body shape of the 3D model. In some embodiments, the system modeling components include a set of properties that can be further modified by a user or inherited from the 3D model, such as dimensions of an object represented by the 3D model. Furthermore, a user can couple system modeling components together by defining interdependent relationships, such as associating state variables, of each component.

The environments menu in components menu 202c can be populated based on environment modeling components associated with a 3D model. For example, in FIG. 2, component menu interface 202c shows various force, displacement, and velocity environments that are associated with the 3D model of the automobile displayed in the 3D model view 204. In some embodiments, the user can be prompted to define environments of the system, which are external inputs or conditions imposed on the system. In some embodiments, the user can specify the environmental input values of each environment selected. In some embodiments, an environment can be specified to be obtained from running a physics solver, such as one of the solvers 154 in FIG. 1. By doing so, a coupling or interdependent relationship can be established between a physics and another aspect of the system.

The requirements menu in component menu 202d can be automatically populated based on relevant objectives or constraints associated with a 3D model, such as the 3D model displayed in the 3D model view 204, once the system model is fully set up. For example, in FIG. 2, component menu interface 202d shows driving performance, comfort, and fuel efficiency requirements that are associated with the 3D model of the automobile displayed in the 3D model view 204. In some embodiments, a user can select one or more requirements from the requirements menu in component menu 202d as objectives and/or constraints for the design problem. The design problem 140 and parts thereof, such as objectives 144 and constraints 142 can be updated based on the selection of the user.

Once displayed, the various modeling components of the component menu interfaces 202a-d can be interacted with by a user of the GUI 106, such as a user selecting aerodynamics in the component menu interface 202a. In some embodiments, a user can interact any number of times with the modeling components in the component menu interfaces 202a-d in any number of ways including, without limitation, selecting one or more modeling components to be associated with one or more portions of the 3D model, selecting one or more modeling components to be associated with one or more other modeling components, adding a modeling component to the system model view 206, adding one or more requirements to the problem definition view 210, editing previously selected modeling components (including editing associated parameters and/or functions) or the associations of the modeling components, removing previously selected modeling components, and other similar interactions.

In some embodiments, the system model view 206 is an interface of the GUI 106 for displaying a system model. The GUI 106 can receive data associated with a system model and display the system model in any technically feasible interface, such as the system model view 206. The system model view 206 can be populated by a system model associated with a system model engine, such as system model engine 130 in FIG. 1, of an application, such as MDO generative design application 120 in FIG. 1. In some embodiments, the system model is associated with a design problem to be solved by the MDO generative design application 120. The system model can be any system model that includes at least a portion of a 3D model, such as a 3D model generated by the 3D model engine 124 in FIG. 1, interdependent design variables associated with the 3D model, and the interdependent relationship of the design variables. In some embodiments, the interdependent design variables can be selected by the user from one or more modeling component interfaces 202a-d. For example, FIG. 2 shows a system model displayed on the system model view 206 that includes an aerodynamic force that has an interdependent relationship with the automobile body shape of the 3D model displayed in the 3D model view 204, active hydraulic suspensions that have an interdependent relationship with the automobile body shape of the 3D model, tire models that have an interdependent relationship with the active hydraulic suspensions, and road displacement environments that have an interdependent relationship with the tire models. The interdependent relationships can be expressed as functions relating parameters associated with the tire models, the hydraulic suspensions, etc., which can be shown by, e.g., clicking on the components of the system model. For example, the functions could relate the force exerted by the ground on the tires to a displacement of the suspension system, relate the displacement of suspensions system to a displacement of the automobile body, etc. The totality of these modeling components, the portion of the 3D shape, and the interdependent relationships between these make up the system model that is displayed on the system model view 206. Once displayed, the system model can be interacted with by a user of the GUI 106. In some embodiments, a user can interact any number of times with the system model in any number of ways including, without limitation, editing, deleting, importing, and/or selecting any of the system model, the components of the system model, or the interdependent relationships within the system model. Any changes to the system model displayed on the system model view 206 can be sent to the system model engine 130 via the interface engine 108 of the MDO generative design application 120.

In some embodiments, the problem definition view 210 is an interface of the GUI 106 for displaying aspects of a design problem, such as design problem 140 in FIG. 1. The GUI 106 can receive data associated with a design problem and display the aspects of the design problem in any technically feasible interface, such as the problem definition view 208. The problem definition view 210 can be populated by a design problem generated by a design problem engine, such as design problem engine 122 in FIG. 1, of an application, such as MDO generative design application 120 in FIG. 1. For example, FIG. 2 shows a design problem with an objective criterion to maximize fuel efficiency, a constraint to satisfy a comfort standard, such as NVH standard 2.1, and various design variables, such as suspension stiffness and car body shape, displayed on the problem definition view 210. The various aspects of the design problem displayed on the problem definition view 210, such as the objectives, constraints, and design variables, can be populated by user selection of various modeling components in the component menu interfaces 202a-d. Once displayed, the aspects of the design problem can be interacted with by a user of the GUI 106. In some embodiments, a user can interact any number of times with the design problem in any number of ways including, without limitation, editing, deleting, importing, or selecting one or more aspects of the design problem, and other similar interactions. Any changes to the design problem displayed on the problem definition view 210 can be sent to the design problem engine 122 via the interface engine 108 of the MDO generative design application 120.

In some embodiments, the computation view 212 is an interface of the GUI 106 for displaying a computational workflow diagram of the design problem, such as design problem 140 in FIG. 1, to be solved during optimization. The GUI 106 can receive data associated with a design problem and display aspects of the design problem in any technically feasible interface, such as the computation view 212. The computation view 212 can be automatically populated when the required information for optimization such as when the design problem 140 has at least one or more objectives, constraints, and design variables. The aspects of the design problem 140, and any interdependent relationships of the aspects of the design problem 140, can be displayed on the computation view 212 as blocks and arrows, respectively. Once displayed, the aspects of the design problem can be interacted with by a user of the GUI 106. In some embodiments, a user can interact any number of times with the computational workflow of the design problem in any number of ways including, without limitation, editing, deleting, importing, or selecting one or more aspects of the design problem, and other similar interactions. Any changes to the design problem displayed on the computation view 212 can be sent to the design problem engine 122 via the interface engine 108 of the MDO generative design application 120. In some embodiments, an optimize button can be automatically generated and displayed on the computation view 212 once the MDO generative design application 120 has the required information for the design problem 140. A user can select the optimize button to perform the optimization techniques disclosed herein based on the design problem 140 represented in the computation view 212. User selection of the optimization button can be sent to the optimization engine 152 to start performing the optimization techniques disclosed herein.

In some embodiments, the natural language interface 132 is an interface of the GUI 106 for receiving natural language input of the user and sending that natural language input to a language model, such as the language model 128 in FIG. 1, for processing. The natural language interface 132 shown in FIG. 2 can be the same as or associated with the natural language interface 132 included in the interface engine 108 shown in FIG. 1. In some embodiments, as an alternative or in addition to a user selecting aspects of the user interface to update a design problem, such as the design problem 140 in FIG. 1, a user can input natural language into the natural language interface 132 for the purposes of updating a design problem or setting up the system model. For exemplary purposes only and not to limit the function of the natural language interface 132, a user can input “I want to maximize the fuel efficiency” to update the design problem 140 to include maximizing fuel efficiency as an objective, such as one of the objectives 144. As another example, the user can input “apply aerodynamic force on the body and displacements on each of the wheels” to update the system model to include an interdependent relationship between aerodynamic force and the body shape of the 3D model, as well as an interdependent relationship between road displacement and the tires of the 3D model. Once input into the natural language interface 132, the GUI 106 can send the natural language input and context data to the language model 128 via the interface engine 108 in FIG. 1, to update the relevant design problem or system model, as described in greater detail below in conjunction with FIGS. 4-6.

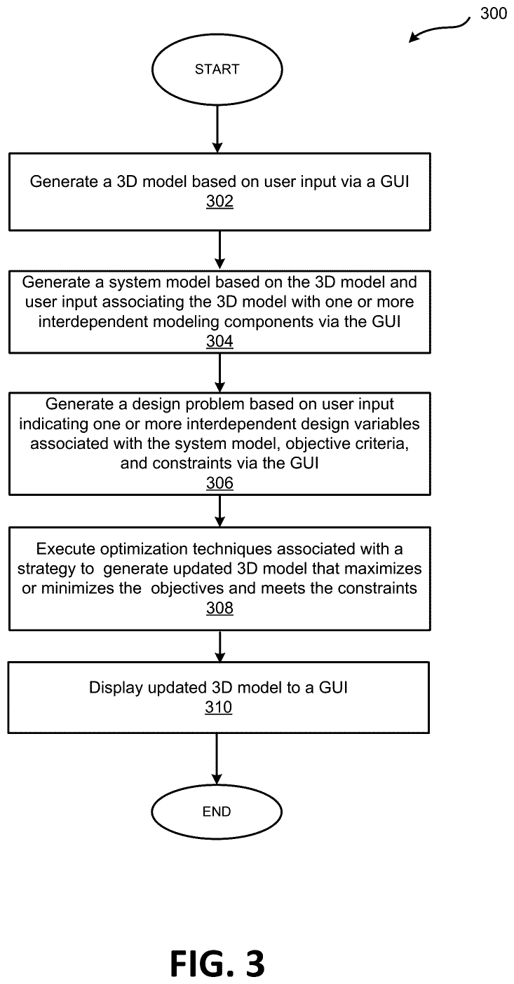

FIG. 3 sets forth a flow diagram of method steps for solving a design problem associated with a 3D model and interdependent design variables, according to various embodiments. Although the method steps are described with reference to the systems of FIGS. 1-2, persons skilled in the art will understand that any system configured to implement the method steps, in any order, falls within the scope of the present invention.

As shown, a method 300 begins at step 302, where the 3D model engine 124 of the MDO generative design application 120 generates a 3D model based on user input from the GUI 106 via the interface engine 108. Alternatively, the 3D model can be imported by the MDO generative design application 120, such as from a file of the 3D model.

At step 304, the system model engine 130 of the MDO generative design application 120 generates a system model based on the 3D model and user input, from the GUI 106 via the interface engine 108, associating the 3D model with one or more interdependent modeling components of the modeling component library 126. The system model includes at least a portion of the 3D model, the interdependent modeling components, and the associations between the interdependent modeling components, as described above in conjunction with FIGS. 1-2.

At step 306, the design problem engine 124 of the MDO generative design application 120 generates the design problem 140 based on user input, from the GUI 106 via the interface 108, including design variables 146 that include one or more interdependent modeling components associated with the system model, objectives 144, and constraints 142, as described above in conjunction with FIGS. 1-2.

At step 308, the optimization engine 152 of the MDO generative design application 120 executes optimization techniques to generate an updated 3D model that maximizes or minimizes the objectives 144 and meets the and constraints 142. Any technically feasible iterative optimization technique or techniques, including techniques that rely on the various solvers disclosed herein, can be used in some embodiments.

Then, at step 310, the design problem engine 124 sends the updated 3D model to the GUI 106 via the interface engine 108 to be displayed.

### Natural Language Interface for Generative Design

FIG. 4 is a conceptual illustration of the interactions between the design problem engine 122 in FIG. 1 and the language model 128 in FIG. 1 to update a design problem, according to various embodiments. In some embodiments, the MDO generative design application 120 in FIG. 1 generates, in any technically feasible fashion, a design problem, such as design problem 140, via the design problem engine 122. The design problem describes the overall design optimization problem and specifies, without limitation, any amount and/or types of ancillary data. The design problem 140 includes, at least, objectives 144, constraints 142, and design variables 146. The design problem engine 122 can generate part or all of the design problem 140 inputs from any or all of the 3D model engine 124, the modeling component library 126, the language model 128, the system model 130, and the interface engine 108, such as components of the modeling component library 420, 3D model 422, and system model 424.

In some embodiments, the MDO generative design application 120 includes a language model, as shown in FIGS. 1 and 4. The language model 128 can be a large language model, a small language model, or any other language model that is compatible with the MDO generative design application 120. The language model 128 can receive natural language input from a natural language interface, such as the natural language interface 132 in FIG. 1. In some embodiments, the language model 128 can be a conventional language model that is compatible with the MDO generative design application 120. In some embodiments, the language model 128 can be a version of a conventional language model that is modified, such as via fine-tuning, to be compatible with the MDO generative design application 120. In some embodiments, the language model 128 can be any type or size language model that is compatible with the MDO generative design application 120. The language model 128 can be part of the MDO generative design application 120 or external to the MDO generative design application 120, such as a language model that executes in the cloud and is accessible via an API.

In order for the language model 128 to process natural language input from the natural language interface 132, the language model 128 can be conditioned with the design problem 140, as shown in FIG. 1, through in-context learning. As shown in FIG. 4, the design problem engine 122 can create context data to condition the language model 128. To create the context data, the design problem engine 122 can receive data associated with components of the modeling component library 420, the 3D model 422, the system model 424, and the design problem 140 from the modeling component library 126, the 3D model engine 124, the system model engine 130, and the design problem engine 122, respectively. In some embodiments, the data associated with the one or more modeling components can be formatted using any formal language, such as XML, JSON, or RDF, or any other compatible format. In some embodiments, semantic information associated with the one or more modeling components, such as a file name or labels of parts thereof, are included in the data representing the one or more modeling components. In some embodiments, the data representing the 3D model can be formatted as a conventional CAD file, or any other compatible format. In some embodiments, semantic information associated with the 3D model, such as a file name or labels of parts, are included in the data representing the 3D model. For example, semantic information about parts of an automobile could be included in a CAD file about a 3D model of the automobile, and the CAD file could further include a list of vertices and edges of the 3D model. In some embodiments, the data representing the system model can be formatted using a system model language, such as SysML or UML, or any other compatible format. In some embodiments, semantic information associated with the system model, such as a file name or labels of components thereof, are included in the data representing the system model. In some embodiments, data representing the design problem 140 can be formatted using any formal language, such as XML, JSON, or RDF, or any other compatible format. In some embodiments, semantic information associated with the design problem 140, such as a file name or labels of parts thereof, are included in the data representing the design problem 140. Once the design problem engine 122 has received the data representing the aforementioned components, models, and design problem, the design problem engine 122 can aggregate the data into a single context data file. Alternatively, the design problem engine 122 can create context data files for each aforementioned components, model, and design problem.

At 404, the design problem engine 122 determines if the language model 128 has the capacity to receive the context document text file as input based on the size of the context data file created in step 402. For example, the design problem engine 122 can determine whether the size of the context data file and other inputs are greater than a context window size of the language model 128.

As 406, if the size of the context document file exceeds the threshold context capacity of the language model 128, the design problem engine 128 can vectorize or otherwise condense the context data file into a design problem embedding, such as design problem embedding 408. In some embodiments, the design problem engine 122 can use an embedding model to vectorize or otherwise condense the context data file. In some embodiments the embedding model is internal to the MDO generative design application 120. In some embodiments, the embedding model is external to the MDO generative design application 120, such as in the cloud. In some embodiments, the design problem embedding 408 is a single condensed context data file. In some embodiments the design problem embedding 408 is multiple condensed context data files, each based on a different component, model, or design problem.

At 410, if the size of the context data file does not exceed the threshold context capacity of the language model 128, the design problem engine 122 can condition the language model 128 based on the context data file as is. Alternatively, if one or more embeddings have been created, such as at step 406, the design problem engine 122 can condition the language model 128 based on portions of the context data file obtained via a vector search using the one or more design problem embeddings.

At 412, once the language model 128 has been conditioned, the language model 128 can start receiving user input. In some embodiments, the user input can include natural language text such as conversational language text from a natural language interface, such as natural language interface 132 in FIG. 1. In some embodiments, the natural language input can include semantic information for the purposes of updating, editing, deleting, and/or creating the aforementioned components, models, and/or design problem, and/or associations between those components, models and/or design problem. For exemplary purposes only and not to limit the function of the natural language interface 132 or the language model 128, a user could input “I want to maximize the fuel efficiency” to update the design problem 140 to specify maximizing fuel efficiency as an objective, such as one of the objectives 144. As another example, the user could input “apply aerodynamic force on the body and displacements on each of the wheels” to update the system model to include an interdependent relationship between aerodynamic force and the body shape of the 3D model, as well as an interdependent relationship between road displacement and the tires of the 3D model.

Once the user input is included in a prompt that is input along with the context data into the language model 128, the language model 128 can update the context data to incorporate the user input. For example, the prompt could ask the language model 128 to update the context data based on the user input. In some embodiments, the design problem engine 122 can perform a search, using any technically feasible measure of vector similarity (e.g., cosine distance) between an embedding of user input and embeddings of the documents or portions thereof, to extract portions of the documents that are most similar to the user input. In such cases, the extracted portions of the documents can be included in context data that is input into the language model 128 along with the prompt. In turn, the language model 128 can update the context data based on the prompt.

Thereafter, the design problem engine can validate the updated context data to check for errors. Any suitable validation can be performed, such as checking that the output data from the language model conforms to a pre-defined schema 128. If a validation error is identified, the design problem engine 122 can ask the language model to iteratively reupdate the context data to correct the validation error, until no validation errors are found. In some embodiments, if validation fails for more than a predefined number of times, the design problem engine 122 can output a notification via the GUI 106 that the natural language input cannot be processed.

The language model 128 can continue to receive natural language input until the user determines the design problem and system model are ready and design optimization can begin. In some embodiments, the MDO generative design application 120 can receive, via the natural language interface, natural language input indicating to start optimization. In some embodiments, the user can press a button that is displayed via the GUI 106 to begin the design optimization

At 414, the language model 128 sends to the design problem engine 122 the updated context document text file. In some embodiments, the language model 128 can send the updated context data file after the updated context data file has been validated. In some embodiments, the design problem engine 122 can use the updated context data file to update the relevant components, models, and/or design problem. In some embodiments, updating the relevant components, models, and/or design problem can include sending the updated context data file to the relevant engine associated with the relevant components, models, and/or design problem. For example, if the updated context data file includes an update to the system model 424, the design problem 122 can send the updated context data file to the system model engine 130. In some embodiments, updating the relevant components, models, and/or design problem can include the design problem engine 122 directly updating the relevant components, models, and/or design problems. For example, if the updated context data includes an update to the system model 424, the design problem 122 can update the system model 424 directly.

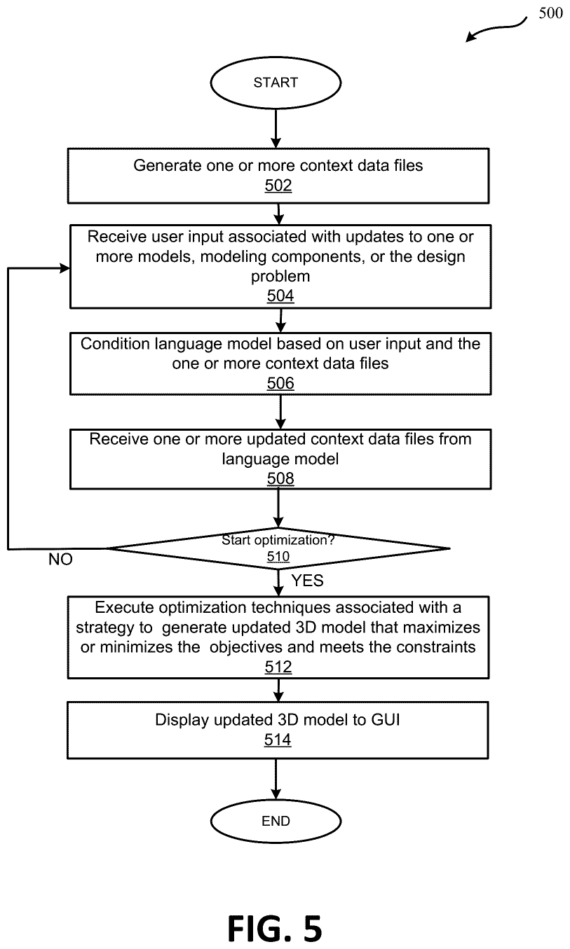

FIG. 5 sets forth a flow diagram of method steps for generating a design using a language model, according to various embodiments. Although the method steps are described with reference to the systems of FIGS. 1-2 and 4, persons skilled in the art will understand that any system configured to implement the method steps, in any order, falls within the scope of the present invention.

As shown, a method 500 begins at step 502, where the design problem engine 122 of the MDO generative design application 120 generates one or more context data files. The design problem engine 122 can create the one or more context data files based on data representing modeling components, the 3D model, the system model, and the design problem, received from the modeling component library 126, the 3D model engine 124, the system model engine 130, and the design problem engine 122, respectively. The design problem engine 122 can condense the one or more context data files via a vectorizer, such as an embedding model, if the size of the one or more context data files are greater than a predetermined capacity of the language model 128.

At step 504, the design problem engine 122 receives user input associated with updates to one or more models, modeling components, or the design problem 140 from the GUI 106 via the natural language interface 132 of the interface engine 108.

At step 506, the design problem engine 122 conditions the language model 128 based on the user input and the one or more context data files. At step 508, the design problem engine 122 can receive one or more updated context data files from the language model 128. The one or more updated context data files include the updates to the one or more models, modeling components, or the design problem 140 based on the user input.

At step 510, the design problem engine 122 determines whether user input has been received that indicates to start optimization of the 3D model. If at step 510, the design problem engine 122 determines that user input indicating to start optimization has not been received, then the method 500 returns to step 504.

If, however, at step 510, the design problem engine 122 determines that user input indicating to start optimization has been received, then the method 500 proceeds directly to step 512. At step 512, the optimization engine 152 of the MDO generative design application 120 executes one or more optimization techniques to maximize or minimize the objectives 144 and meet the and constraints 142. Any technically feasible iterative optimization technique or techniques, including techniques that rely on the various solvers disclosed herein, can be used in some embodiments.

At step 514, the design problem engine 124 sends the updated 3D model to the GUI 106 via the interface engine 108 to be displayed to a user.

### Generative Design Techniques for Free-Form Deformation of 3D Models

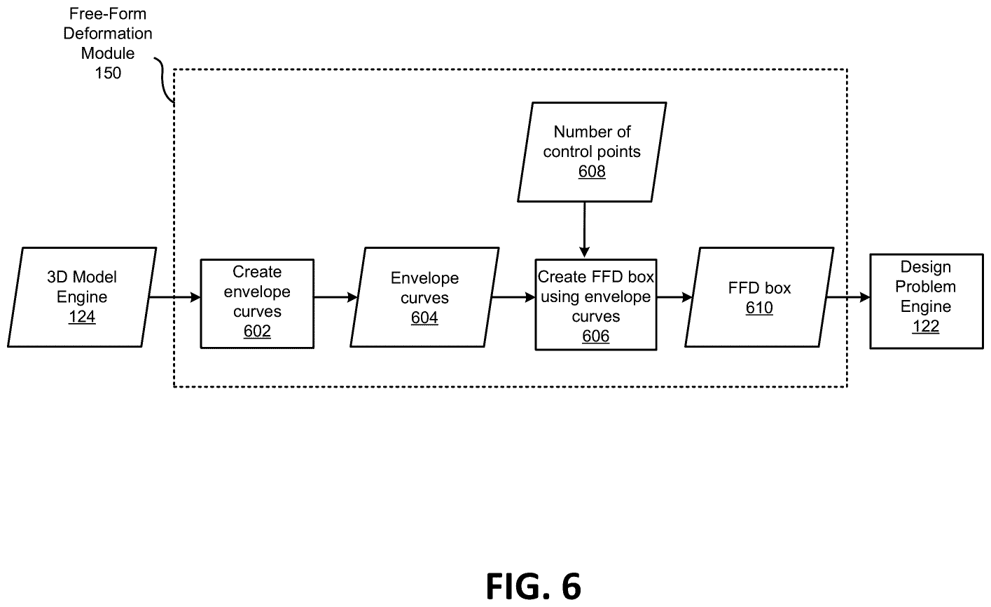

FIG. 6 is a conceptual illustration of how the free-form deformation module 150 in FIG. 1 can generate a free-form deformation box for optimization, according to various embodiments. As shown, the 3D model engine 124 includes a free-form deformation module 150.

Illustratively, the free-form deformation module 150 generates, at 602, a set of envelope curves 604 along a portion of the 3D model, received from the 3D model engine 124. The generation of the set of envelope curves 604 can be based on user input. Any number and/or types of user input can be received from the GUI 106, via the interface engine 108. In some embodiments, the input is based on a user created sketch of the envelope curves 604 along the portion of the 3D model. The set of envelope curves 604 define a portion of the geometry of the 3D model that will change during optimization.

At 606, once the set of envelope curves 604 is created, the free-form deformation module 150 generates a free-form deformation box 610 that encompasses the set of envelope curves and includes a user input number of control points 608. The user input number of control points 608 can be received from GUI 106 via the interface engine 108. In some embodiments, the free-form deformable box 610 can be represented as a 3D box over of the portion of the 3D model, and control points on the free-form deformable box 610 can be linked to the envelope curves 604 such that changes in the free-form deformable box 610 and the control points thereon result in changes to the envelope curves 604 and thereby the geometry of the 3D model. In some embodiments, the free-form deformation box 610 can be modeled using B-spline functions, but other compatible modeling functions can also be used. In some embodiments, the free-form deformable box 610 can be generated from the envelope curves 604 and user input control points 608 in any technically feasible manner, including using known techniques.

At 612, once the free-form deformation box 610 with control points is generated, the free-form deformation module 150 can send data representing the free-form deformation box 610, the set of control points, one or more constraints, such as constraints 142, and one or more objectives, such as objectives 144, to the design problem engine 122. The one or more constraints and one or more objectives can be based on user input associated with the parametrized portion of the 3D model. For example, the user input can indicate that the parametrized portion of the 3D model, such as spoiler of an automobile, should weigh no more than 10 lbs and be twisted to a particular angle or moved up or down to maximize drag. The user input that indicates the one or more constraints and one or more objectives can be received at any point during or after 602. The design problem engine 122 can then generate a design problem, such as design problem 140 based on the data about the free-form deformation box 610, the set of control points, the one or more constraints 142 and one or more objectives 144. The one or more locations of the set of control points can be used by the design problem engine 122 as the design variables 146 of the design problem 140, and the design problem 140 can be limited to certain aspects of the control points, such as an associated twist angle or vertical position. The design problem engine 122 can then send the design problem 140 to the optimization engine, such as optimization engine 152 in FIG. 1, to be optimized

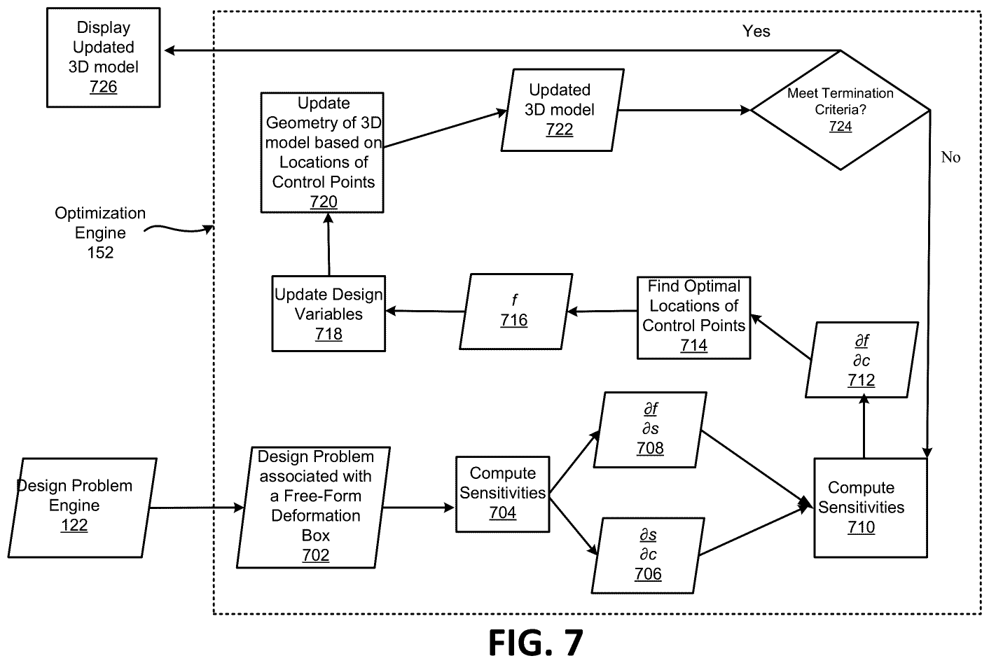

FIG. 7 is a conceptual illustration of how the optimization engine 152 in FIG. 1 can optimize a portion of a 3D model represented by a free-form deformation box, according to various embodiments. As shown, the 3D model engine 124 includes a free-form deformation module 150. The free-form deformation box module 150 can generate a free-form deformation box as shown in FIG. 6 or via other techniques disclosed herein. The free-form deformation box encompasses a set of envelope curves that parametrize a portion of a 3D model, and the free-form deformation box can include one or more control points on the free-for deformation box. The free-form deformation module 150 can send data representing the free-form deformation box and the set of control points to the design problem engine 122 to generate a design problem, such as design problem 702, based on the free-form deformation box where the locations of the set of control points are the design variables, such as one or more of the design variables 146 in FIG. 1. The design problem engine 122 can then send the design problem associated with the free-form deformation box 702 to the optimization engine, such as optimization engine 152 in FIG. 1, to be optimized.

As shown in FIG. 7, once the design problem associated with the free-form deformation box 702 is received by the optimization engine 152, the optimization engine 152 can start solving the design problem 702 or a portion thereof. The optimization engine 152 can solve the design problem 702 or a portion thereof by iteratively performing one or more optimization techniques, such as one or more known optimization algorithms, on the design variables (including the locations of the control points of the free-form deformation box) of the design problem 702. During the optimization, an objective function f can be used to find the optimal locations of the one or more control points based on one or more objectives and the one or more constraints. The one or more objectives and the one or more constraints can be based on user input associated with the parametrized portion of the 3D model. For example, the user input can indicate that the parametrized portion of the 3D model, such as spoiler of an automobile, should weigh no more than 10 lbs and shaped to maximize drag.

At 704, the optimization engine 152 can simultaneously compute a first derivative indicating a sensitivity, denoted as sensitivity

$$\frac{\partial s}{\partial c} 706 ,$$

associated with a change in the geometry of the 3D model with respect to a change in one or more locations of the one or more control points and a second derivative indicating a sensitivity, denoted as

$$\frac{\partial f}{\partial s} 708 ,$$

associated with a change in an objective function with respect to the change in the geometry of the 3D model. In some embodiments, the sensitivity

$$\frac{\partial s}{\partial c} 706$$

can be obtained using a tree-form deformation box construction technique, such as by taking the derivatives of B-spline functions that model the free-form deformation box. In some embodiments, the sensitivity

$$\frac{\partial f}{\partial s} 708$$

can be computed using a physics solver.

At 710, the optimization engine 152 can use the two sensitivities 706 and 708 to compute a third derivative indicating a sensitivity, denoted as associated with

$$\frac{\partial f}{\partial c} 712 ,$$

a change in the objective function with respect to the change in one or more locations of the control points.

At 714, the optimization engine 152 can use the third sensitivity to find the optimal locations of the one or more control points, denoted as f 716. For example, in some embodiments, a gradient-based optimizer can be used to find the optimal locations of the one or more control points using the third sensitivity.

A 718, the optimization engine 152 can change the current locations of the one or more control points to the optimal locations of the one or more control points f 716. In some embodiments, the optimization engine 152 can send the value of f to the free-form deformation module 150 to update the current locations of the one or more control points to the optimal locations.

At 720, the optimization engine 152 can update the geometry of the 3D model by using the optimal locations of the one or more control points to change the location of the corresponding set of envelope curves, creating an updated 3D model 722.

At 724, the optimization engine 152 checks if the updated 3D model 722 meets the one or more termination criteria, such as a maximum number of iterations having been performed or the computed value of an objective function not improving over one or more iterations. If the one or more termination criteria are not met, the optimization engine 152 can perform another iteration of optimization starting at 710.

On the other hand, if the termination criteria are met, the optimization engine can send the updated 3D model to the interface engine 108 for display via the GUI 106 at 726.

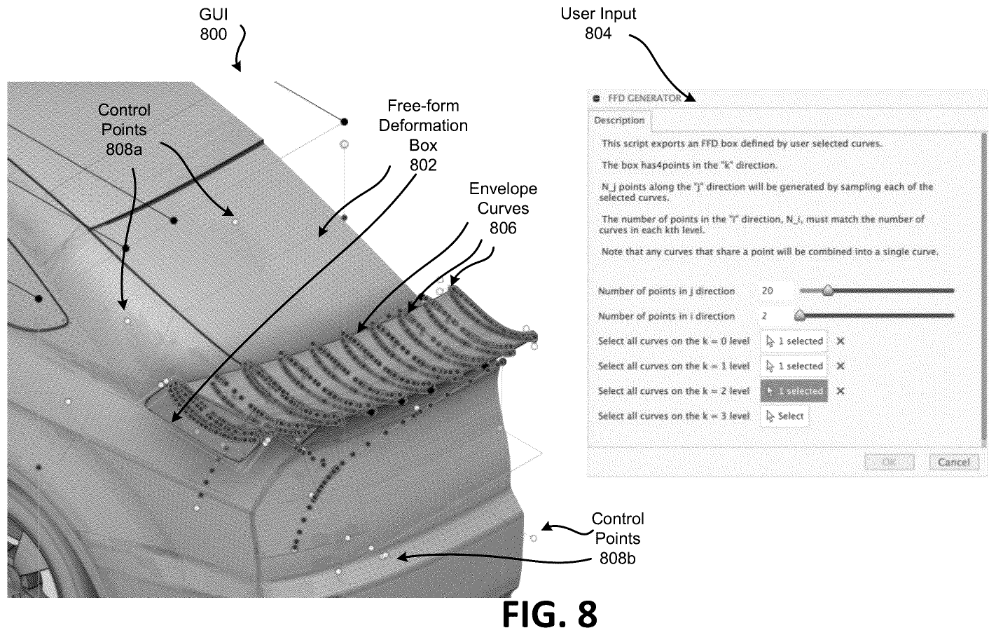

FIG. 8 illustrates an exemplary user interface for creating free-form boxes, according to various embodiments. As shown, the GUI 106 in FIG. 1 can display a free-form deformation box, such as free-form deformation box 802. The GUI 106 can receive various user inputs, such as user input 804, from a user and send the user input 804 via an interface engine, such as interface engine 108 in FIG. 1, to a free-form deformation module, such as free-form deformation module 150 in FIG. 1, to facilitate the generation of the free-form deformation box 802. The free-form deformation module can be part of a 3D model engine, such as 3D model engine 124 in FIG. 1. In some embodiments, the GUI 106 displays an interactive window next to a 3D model to facilitate user input for generating the free-form deformation box 802. In some embodiments, the free-form deformation box 802 can be generated based on user input, such as user input 804, indicating to parameterize a portion of a 3D model for optimization. For example, as shown in FIG. 4, the GUI 106 depicts an interactive window that can receive user input 804 to generate a free-form deformation box based on design variables, such as a number of control points or a number of envelope curves, input by a user. In some embodiments, the user input 804 can include natural language received by a natural language interface, such as natural language interface 132 in FIG. 1, that is parsed by a language model, such as language model 128 in FIG. 1.

The user input 804 can be used to generate envelope curves 806 around the portion of the 3D model that is to be parametrized for optimization. The number of envelope curves and the placement of the envelope curves can be based on the user input 804. In some embodiments, the user can sketch the envelope curves directly onto the 3D model. The envelope curves can be generated around the portion of the 3D model indicated by the user input 804. The user input 804 can further indicate to select specific envelope curves for use in parametrizing the portion of the 3D model. For example, the user input 804 can indicate to use envelope curves on a specific planar level of the 3D model to further control the parametrization of the 3D model. Once the envelope curves 804 are generated, the free-form deformation box 802 can be generated around a second portion of the 3D model, depicted in FIG. 4 as a lined-box around a portion of a 3D model of an automobile. As shown in FIG. 4, the second portion of the 3D model that includes the free-form deformation box 802 encompasses the envelope curves 806 and the parameterized portion of the 3D model. Next, control points 808a and 808b can be automatically generated on the free-from deformation box 802, depicted in FIG. 4 as dots connected to the lined-box of the free-forward deformation box 802. The number of control points in each direction can be determined by the user input 804. Once the control points have been generated, the GUI 106 can send data representing the control points as design variable to an optimization engine, such as optimization engine 152 in FIG. 1, to optimize the parametrized portion of the 3D model by optimizing the control points and moving the envelop curves 806 and associated geometry of the 3D according to the optimized control points.

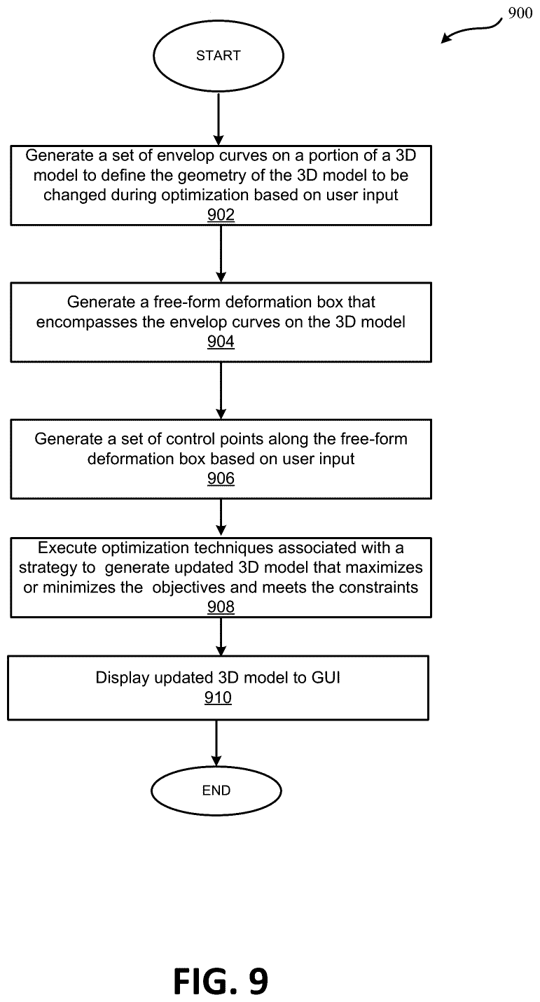

FIG. 9 sets forth a flow diagram of method steps for generating a design using a free-form deformation box, according to various embodiments. Although the method steps are described with reference to the systems of FIGS. 1-2, 4, and 6-7, persons skilled in the art will understand that any system configured to implement the method steps, in any order, falls within the scope of the present invention.

As shown, a method 900 begins at step 902, where the free-form deformation module 150 of the MDO generative design application 120 generates a set of envelope curves along a portion of a 3D model, received from the 3D model engine 124, to define the geometry of the 3D model that will change during optimization. The generation of the set of envelope of curves can be based on any number and/or types of input received from the GUI 106, via the interface engine 108. In some embodiments, the input is based on a user created sketch of the envelope curves along the portion of the 3D model.

At step 904, the free-form deformation module 150 generates a free-form deformation box 410 that encompasses the set of envelope curves. At step 906, the free-form deformation module 150 can generate a set of control points along each direction of the free-form deformation box based on user input. The user input can include a number of control points to be placed on the free-form deformation box. The user input can be received from GUI 106 via the interface engine 108. A change in the location of the set of control points corresponds to a change in the location of the set of envelope curves and thereby the geometry of the 3D model. The free-form deformation module 150 can send data representing the free-form deformation box, the set of control points, and one or more objectives, such as objectives 144, to the design problem engine 122. The one or more objectives can be based on additional user input associated with the portion of the 3D model. The design problem engine 122 can then generate the design problem 140 based on the data representing the free-form deformation box, the set of control points, and one or more objectives. The one or more locations of the set of control points can be used by the design problem engine 122 as the design variables 146 of the design problem 140. The design problem engine 122 can then send the design problem 140 to the optimization engine 152.

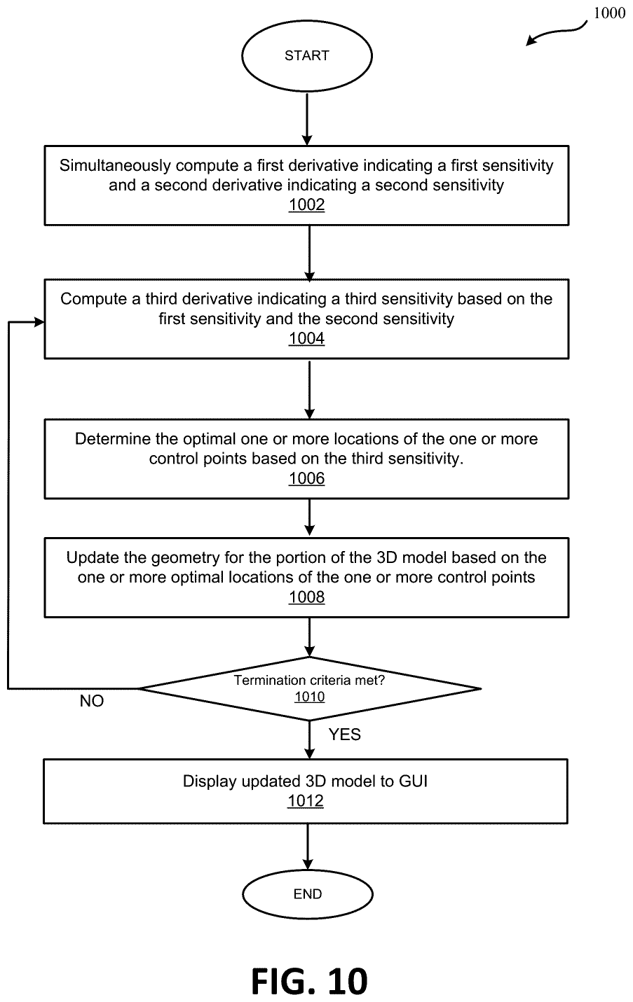

At step 908, the MDO generative design application 120 executes one or more optimization techniques to generate an updated 3D model that maximizes or minimizes the objectives 144 and meets the and constraints 142. Any technically feasible iterative optimization technique or techniques, including the technique described below and in conjunction with FIG. 10.

At step 910, the design problem engine 124 sends the updated 3D model to the GUI 106 via the interface engine 108 to be displayed to a user.

FIG. 10 sets forth a more detailed flow diagram for executing optimization techniques to generate an updated 3D model at step 908 of the method 900, according to various embodiments. Although the method steps are described with reference to the systems of FIGS. 1-2, 4, and 6-7, persons skilled in the art will understand that any system configured to implement the method steps, in any order, falls within the scope of the present invention.

As shown, a method 1000 begins at step 1002, where the optimization engine 152 of the MDO generative design application 120 simultaneously computes a first derivative indicating a sensitivity, denoted as

$$\frac{\partial s}{\partial c} ,$$

associated with a change in the geometry for the portion of the 3D model with respect to a change in one or more locations of the one or more control points and a second derivative indicating a sensitivity, denoted as

$$\frac{\partial f}{\partial s} ,$$

associated with a change in the value of the objective function with respect to the change in the geometry for the portion of the 3D model.

At step 1004, the optimization engine 152 computes a third derivative indicating a sensitivity, denoted as

$$\frac{\partial f}{\partial c} ,$$

associated with a change in the value of the objective function with respect to the change in the one or more locations of the one or more control points based on the first and second sensitivities.

At step 1006, the optimization engine 152 determines one or more optimal locations of the one or more control points based on the third sensitivity and an associated derivative. For example, in some embodiments, a gradient-based optimizer can be used to find the optimal location(s) of the control point(s).

At step 1008, the optimization engine 152 updates the geometry for the portion of the 3D model based on the one or more optimal locations of the one or more control points. Because the control point(s) are linked to the envelope curves and a change in location(s) of the control point(s) results in a change in the location(s) of the envelope curve(s), the geometry of the portion of the 3D model will change based on a change in the location(s) of the control point(s).

At step 1010, the optimization engine 152 determines if termination criteria been met. For example, in some embodiments, the termination criteria can be a maximum number of iterations having been performed or the computed value of an objective function not improving over one or more iterations.

If, at step 1010, the optimization engine 152 determines that the termination criteria have not been met, then the method 1000 returns to step 1004, where the optimization engine 152 computes the third derivative again. If, however, at step 1010 the updated 3D model meets the termination criteria, then the method 1000 proceeds directly to step 1012. At step 1012, the design problem engine 124 sends the updated 3D model to the GUI 106 via the interface engine 108 to be displayed.

In sum, the disclosed techniques can leverage MDO in generative design to solve a design problem associated with a 3D model and interdependent design variables. In some embodiments, an MDO generative design application can generate a 3D model. The MDO generative design application can recommend relevant modeling components based on the 3D model to generate a system model. The modeling components can include physics, 3D model components, and environments that affect the 3D model. Each modeling component can be interdependent on another modeling component and/or a portion of the 3D model and contributes to the overall behavior of the system model. Parameters of the interdependent modeling components and the interdependencies can be used as design variables for a design problem associated with the 3D model. Once the system model is generated, the MDO generative design application can generate a design problem based on one or more interdependent design variables, one or more objectives to be maximized or minimized, and one or more constraints. The MDO generative design application includes an optimization engine that can solve the design problem by iteratively performing optimization operations on the interdependent design variables to generate an 3D model that maximizes or minimizes the objectives and meets the constraints, while simultaneously considering the effect of each interdependency of the design variables.

In some embodiments, the disclosed techniques can leverage a natural language interface to augment the creation of a design problem for optimization and/or a system model. In some embodiments, the MDO generative design application includes a language model that is conditioned with the current design problem. The current design problem can include information associated with the 3D model, relevant system components, objectives, constraints, and the system model. The MDO generative design application can include a natural language interface that can receive natural language input by a user, which is then input into the language model along with the current design problem as context in order to generate an update to the current design problem. The updates to the current design problem can be validated for errors. If an error exists, the language model can iteratively reupdate the current design problem until no errors are present or a maximum number of attempts has occurred. Once the updated design problem is ready for optimization, the language model can send the updated design problem to the optimization engine of the MDO generative design application. The optimization engine can then generate an optimized design according to the design problem and disclosed techniques herein.

In some embodiments, the disclosed techniques can leverage free-form deformation to define a portion of a 3D model as the design problem to be solved in generative design. In some embodiments, the MDO generative design application 120 includes a free-form deformation module 150 that can parameterize the geometry of a portion of a 3D model via a free-form deformation box. In some embodiments, user input is received indicating one or more objectives. In some embodiments, the received one or more objectives indicate that a free-form deformation box should be created. In some embodiments, the received user input indicates that a free-form deformation box should be created. Based on the user input, the free-form deformation module 150 can create a set of envelope curves along a portion of the 3D model. The set of envelope curves define the geometry of the 3D model that will change during optimization. Once the set of envelope curves is created, the free-form deformation module creates a free-form deformation box that encompasses the set of envelope curves, which can be represented as a 3D box over of the portion of the 3D model. A set of control points can be created along each direction of the free-form deformation box. A change in the location of the set of control points corresponds to a change in the location of the set of envelope curves and thereby the geometry of the 3D model. Once the control points are created, the free-form deformation module can send the free-form deformation box, the set of control points, and one or more objectives to the optimization engine. The set of control points can be used by the optimization engine as the design variables for the design problem. The optimization engine can then solve the design problem by iteratively performing optimization operations based on the design problem. In some embodiments, the optimization engine can simultaneously compute a first sensitivity associated with a change in the geometry of the 3D shape with respect to a change in one or more locations of the one or more control points and a second sensitivity associated with a change in an objective function with respect to the change in the geometry of the 3D shape. Using the two sensitivities, the optimization engine can compute a third sensitivity associated with a change in the objective function with respect to the change in one or more locations of the control points. The third sensitivity can then be used to generate the optimal geometry of the 3D model.

At least one technical advantage of the disclosed techniques relative to the prior art is that, with the disclosed techniques, a design problem associated with a 3D model and interdependent system components can be specified and solved much faster via a single user interface. The 3D model does not need to be exported to and modified in a separate application prior to solving the design problem. In that regard, the disclosed techniques are not limited by the skill needed to write expert level code for the separate application, nor are the disclosed techniques limited by a closed design space of pre-built components. As a result, the likelihood that the 3D model is accurately optimized to meet user objectives is increased.

Another technical advantage of the disclosed techniques relative to the prior art is that, with the disclosed techniques, a design problem associated with a 3D model and interdependent system components can be specified and solved more accurately using natural language user inputs. Although design problems with interdependent design variables are more complex, using trained language models and a natural language interface to augment the creation of a design problem enables a MDO generative design application to explore the design space in a more directed and therefore accurate fashion. As a result, the likelihood that the 3D model is accurately optimized to meet user objectives is increased.

Another technical advantage of the disclosed techniques relative to the prior art is that, with the disclosed techniques, a design problem associated with a 3D model can be solved with more control over a portion of the geometry of the 3D model. By focusing the design problem on a portion of the 3D model instead of the entirety of the 3D model, solutions that offer limited modifications to only the portion of the 3D model, while preserving the overall geometry of the 3D model, can be efficiently found. As a result, the likelihood that the 3D model is accurately optimized to meet user objectives is increased.

These technical advantages provide one or more technological improvements over prior art approaches.

1. In some embodiments, a computer-implemented method for generating optimized designs comprises receiving first user input that includes a plurality of interdependent design variables and a three-dimensional (3D) shape; generating, based on the first user input, a design problem that includes the plurality of interdependent design variables and the 3D shape, wherein the design problem defines one or more associations between the plurality of interdependent design variables and a geometry for the 3D shape; receiving second user input that includes one or more objectives associated with the design problem and one or more constraints associated with the design problem; and iteratively performing, based on the design problem, one or more operations on the plurality of interdependent design variables and the geometry for the 3D shape to generate an updated geometry for the 3D shape.

2. The computer-implemented method of clause 1, wherein each interdependent design variable included in the plurality of the interdependent design variables is associated with a different modeling component.

3. The computer-implemented method of clause 2, wherein the different modeling components comprise at least one of: a type of physics affecting at least one portion of the 3D shape; an environment affecting at least one portion of the 3D shape; or a system modeling component affecting at least one portion of the 3D shape.

4. The computer-implemented method of any of clauses 1-3, wherein at least one interdependent design variable included in the plurality of interdependent design variables is interdependent with respect to at least one other interdependent design variable included in the plurality of interdependent design variables.

5. The computer-implemented method of any of clauses 1-4, wherein both the first user input and the second user input are received via a natural language interface.

6. The computer-implemented method of any of clauses 1-5, wherein a physics solver iteratively performs the one or more operations on the plurality of interdependent design variables and the geometry for the 3D shape.

7. The computer-implemented method of any of clauses 1-6, wherein iteratively performing the one or more operations includes executing at least a gradient-based algorithm.

8. The computer-implemented method of any of clauses 1-7, further comprising outputting, via a user interface, a rendered 3D model that includes the updated geometry for the 3D shape.

9. The computer-implemented method of any of clauses 1-8, further comprising outputting, via a user interface, a computational workflow diagram that indicates the 3D shape, the plurality of interdependent design variables, the one or more associations between the plurality of interdependent design variables and the geometry for the 3D shape, the one or more objective criteria, and the one or more constraints.

10. The computer-implemented method of any of clauses 1-9, further comprising receiving third user input that includes a request to perform the one or more operations on the plurality of interdependent design variables and the geometry for the 3D shape to generate the updated geometry for the 3D shape.

11. In some embodiments, one or more non-transitory computer-readable media including instructions that, when executed by one or more processors, cause the one or more processors to generate optimized designs by performing the steps of: receiving first user input that includes a plurality of interdependent design variables and a three-dimensional (3D) shape; generating, based on the first user input, a design problem that includes the plurality of interdependent design variables and the 3D shape, wherein the design problem defines one or more associations between the plurality of interdependent design variables and a geometry for the 3D shape; receiving second user input that includes one or more objectives associated with the design problem and one or more constraints associated with the design problem; and iteratively performing, based on the design problem, one or more operations on the plurality of interdependent design variables and the geometry for the 3D shape to generate an updated geometry for the 3D shape.

12. The one or more non-transitory computer-readable media of clause 11, wherein each interdependent design variable included in the plurality of the interdependent design variables is associated with a different modeling component.

13. The one or more non-transitory computer-readable media of clause 12, wherein the different modeling components include at least one of: a type of physics affecting at a least one portion of the 3D shape; an environment affecting at least one portion of the 3D shape; or a system modeling component affecting at least one portion of the 3D shape.

14. The one or more non-transitory computer-readable media of any of clauses 11-13, wherein at least one interdependent design variable included in the plurality of interdependent design variables is interdependent with respect to at least one other interdependent design variable included in the plurality of interdependent design variables.

15. The one or more non-transitory computer-readable media of any of clauses 11-14, wherein both the first user input and the second user input are received via a natural language interface and processed via a language model.

16. The one or more non-transitory computer-readable media of any of clauses 11-15, wherein a physics solver iteratively performs the one or more operations on the plurality of interdependent design variables and the geometry for the 3D shape.

17. The one or more non-transitory computer-readable media of any of clauses 11-16, wherein the instructions, when executed by one or more processors, further cause the one or more processors to perform the step of outputting a user interface, wherein the user interface includes at least a first section displaying the 3D shape, a second section displaying one or more modeling components, a third section displaying a system associated with the 3D shape and the one or more interdependent design variables, a fourth section displaying a natural language interface, a fifth section displaying the design problem, and sixth section displaying a computational workflow diagram associated with the system and the design problem.

18. The one or more non-transitory computer-readable media of any of clauses 11-17, wherein the one or more objectives include an objective function associated with the 3D shape to maximize or minimize.

19. The one or more non-transitory computer-readable media of any of clauses 11-18, wherein the one or more constraints include at least one requirement for the 3D shape associated with a standards regulation.

20. In some embodiments, a system comprises one or more memories storing instructions and one or more processors coupled to the one or more memories that, when executing the instructions, perform the steps of: receiving first user input that includes a plurality of interdependent design variables and a three-dimensional (3D) shape; generating, based on the first user input, a design problem that includes the plurality of interdependent design variables and the 3D shape, wherein the design problem defines one or more associations between the plurality of interdependent design variables and a geometry for the 3D shape; receiving second user input that includes one or more objectives associated with the design problem and one or more constraints associated with the design problem; and iteratively performing, based on the design problem, one or more operations on the plurality of interdependent design variables and the geometry for the 3D shape to generate an updated geometry for the 3D shape.

21. In some embodiments, a computer-implemented method for generating designs using a natural language interface coupled to a language model comprises receiving natural language input associated with one or more updates to a current design problem that defines one or more associations between a plurality of interdependent design variables and geometry for a three-dimensional (3D) shape; sending the natural language input to the language model for processing; receiving, from the language model, a design problem that includes the one or more updates to the current design problem; and iteratively performing, based on the design problem, one or more operations on the plurality of interdependent design variables and the geometry for the 3D shape to generate an updated geometry for the 3D shape.

22. The computer-implemented method of clause 21, wherein the language model is conditioned based on context data that includes data representing the current design problem.

23. The computer-implemented method of any of clauses 21-22, wherein sending the natural language input to the language model comprises generating an embedding of at least one portion of the current design problem.

24. The computer-implemented method of any of clauses 21-23, wherein sending the natural language input to the language model comprises generating a prompt based on the natural language input and the current design problem.

25. The computer-implemented method of any of clauses 21-24, wherein the language model is a large language model.

26. The computer-implemented method of any of clauses 21-25, further comprising validating the design problem that includes the one or more updates to the current design problem.

27. The computer-implemented method of any of clauses 21-26, wherein the natural language input is received via the natural language interface.

28. The computer-implemented method of any of clauses 21-27, wherein a physics solver iteratively performs the one or more operations on the plurality of interdependent design variables and the geometry for the 3D shape.

29. The computer-implemented method of any of clauses 21-28, wherein each interdependent design variable included in the plurality of the interdependent design variables is associated with at least one of: a type of physics affecting at a least one portion of the 3D shape; an environment affecting at least one portion of the 3D shape; or a system modeling component affecting at least one portion of the 3D shape.

30. The computer-implemented method of any of clauses 21-29, wherein at least one interdependent design variable of the plurality of interdependent design variables is interdependent with at least one other interdependent design variable of the plurality of interdependent design variables.

31. In some embodiments, one or more non-transitory computer-readable media including instructions that, when executed by one or more processors, cause the one or more processors to generate optimized designs using a natural language interface coupled to language model by performing the steps of: receiving natural language input associated with one or more updates to a current design problem that defines one or more associations between a plurality of interdependent design variables and geometry for a three-dimensional (3D) shape; sending the natural language input to the language model for processing; receiving, from the language model, a design problem that includes the one or more updates to the current design problem; and iteratively performing, based on the design problem, one or more operations on the plurality of interdependent design variables and the geometry for the 3D shape to generate an updated geometry for the 3D shape.

32. The one or more non-transitory computer-readable media of clause 31, wherein the language model is conditioned based on context data that includes data representing the current design problem.

33. The one or more non-transitory computer-readable media of any of clauses 31-32, wherein sending the natural language input to the language model further comprises generating an embedding of at least one portion of the current design problem.

34. The one or more non-transitory computer-readable media of any of clauses 31-33, wherein sending the natural language input to the language model comprises generating a prompt based on the natural language input and the current design problem.

35. The one or more non-transitory computer-readable media of any of clauses 31-34, wherein the language model is a large language model.

36. The one or more non-transitory computer-readable media of any of clauses 31-35, further comprising validating the design problem that includes the one or more updates to the current design problem.

37. The one or more non-transitory computer-readable media of any of clauses 31-36, further comprising validating, based on a predefined schema, the design problem that includes the one or more updates to the current design problem.

38. The one or more non-transitory computer-readable media of any of clauses 31-37, wherein the updated geometry for the 3D shape meets one or more constraints associated with the design problem and either maximizes or minimizes an objective function associated with the design problem.

39. The one or more non-transitory computer-readable media of any of clauses 31-3, wherein receiving the natural language input further comprises receiving natural language input that indicates a request to optimize the 3D shape.

40. In some embodiments, a system comprises: one or more memories storing instructions; and one or more processors coupled to the one or more memories that, when executing the instructions, perform the steps of: receiving natural language input associated with one or more updates to a current design problem that defines one or more associations between a plurality of interdependent design variables and geometry for a three-dimensional (3D) shape; sending the natural language input to the language model for processing; receiving, from the language model, a design problem that includes the one or more updates to the current design problem; and iteratively performing, based on the design problem, one or more operations on the plurality of interdependent design variables and the geometry for the 3D shape to generate an updated geometry for the 3D shape.

41. A computer-implemented method for generating designs using free-form deformation comprising: generating, based on user input, one or more envelope curves located on a first portion of a three-dimensional (3D) shape; generating, based on the one or more envelope curves, a free-form deformation box that comprises one or more control points; determining a design problem that includes one or more design variables associated with one or more locations of the one or more control points, wherein the design problem defines one or more associations between the one or more design variables and a geometry for the first portion of the 3D shape; iteratively performing, based on the design problem, one or more operations on the one or more design variables to generate one or more updated envelope curves on the first portion of the 3D shape, wherein the one or more updated envelope curves define an updated geometry for the first portion of the 3D shape.

42. The computer-implemented method of clause 41, wherein a change in the one or more locations of the one or more control points corresponds to a change in one or more locations of the one or more envelope curves.

43. The computer-implemented method of any of clauses 41-42, wherein the change in the one or more locations of the one or more envelope curves corresponds to a change in the geometry for the first portion of the 3D shape.

44. The computer-implemented method of any of clauses 41-43, wherein iteratively performing one or more operations includes at least generating, based on one or more sensitivities associated with the one or more locations of the one or more control points, the one or more updated envelope curves on the first portion of the 3D shape.

45. The computer-implemented method of any of clauses 41-44, wherein a physics solver iteratively performs the one or more operations on the one or more design variables.

46. The computer-implemented method of any of clauses 41-45, wherein the request further includes a number of control points to be generated for the free-form deformation box.

47. The computer-implemented method of any of clauses 41-46, wherein the request further includes a number of envelope curves to be generated on the first portion of the 3D shape.

48. The computer-implemented method of any of clauses 41-47, further comprising receiving second user input specifying the design problem.

49. The computer-implemented method of any of clauses 41-48, wherein the free-form deformation box is generated within a computer-aided design environment and encompasses the first portion of the 3D shape, and wherein the one or more control points are located on the free-form deformation box.

50. The computer-implemented method of any of clauses 41-49, further comprising outputting, to a user interface, a rendered 3D model that includes the updated geometry for the portion of the 3D shape.

51. In some embodiments, one or more non-transitory computer-readable media including instructions that, when executed by one or more processors, cause the one or more processors to generate optimized designs by performing the steps of: generating, based on user input, one or more envelope curves located on a first portion of a three-dimensional (3D) shape; generating, based on the one or more envelope curves, a free-form deformation box that comprises one or more control points; determining a design problem that includes one or more design variables associated with one or more locations of the one or more control points, wherein the design problem defines one or more associations between the one or more design variables and a geometry for the first portion of the 3D shape; iteratively performing, based on the design problem, one or more operations on the one or more design variables to generate one or more updated envelope curves on the first portion of the 3D shape, wherein the one or more updated envelope curves define an updated geometry for the first portion of the 3D shape.

52. The one or more non-transitory computer-readable media of clause 51, wherein a change in the one or more locations of the one or more control points corresponds to a change in one or more locations of the one or more envelope curves.

53. The one or more non-transitory computer-readable media of any of clauses 51-52, wherein the change in the one or more locations of the one or more envelope curves corresponds to a change in the geometry for the portion of the 3D shape.

54. The one or more non-transitory computer-readable media of any of clauses 51-53, wherein iteratively performing one or more operations includes at least generating, based on one or more sensitivities associated with the one or more locations of the one or more control points, the one or more updated envelope curves on the first portion of the 3D shape.

55. The one or more non-transitory computer-readable media of any of clauses 51-54, wherein the request further includes a number of control points to be generated using the free-form deformation box.

56. The one or more non-transitory computer-readable media of any of clauses 51-55, wherein the request further includes a number of envelope curves to be generated on the first portion of the 3D shape.

57. The one or more non-transitory computer-readable media of any of clauses 51-56, wherein the instructions, when executed by the one or more processors, further cause the one or more processors to perform the step of receiving second user input specifying an objective function associated with the first portion of the 3D shape to maximize or minimize.

58. The one or more non-transitory computer-readable media of any of clauses 51-57, wherein the instructions, when executed by the one or more processors, further cause the one or more processors to perform the step of receiving second user input specifying at least one requirement for the first portion of the 3D shape associated with a standards regulation.

59. The one or more non-transitory computer-readable media of any of clauses 51-58, wherein iteratively performing one or more operations on the one or more design variables is further based on receiving a second user input to optimize the first portion of the 3D shape.

20. In some embodiments, a system comprises: one or more memories storing instructions; and one or more processors coupled to the one or more memories that, when executing the instructions, perform the steps of: generating, based on user input, one or more envelope curves located on a first portion of a three-dimensional (3D) shape; generating, based on the one or more envelope curves, a free-form deformation box that comprises one or more control points; determining a design problem that includes one or more design variables associated with one or more locations of the one or more control points, wherein the design problem defines one or more associations between the one or more design variables and a geometry for the first portion of the 3D shape; iteratively performing, based on the design problem, one or more operations on the one or more design variables to generate one or more updated envelope curves on the first portion of the 3D shape, wherein the one or more updated envelope curves define an updated geometry for the first portion of the 3D shape.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for generating designs using a natural language interface coupled to a language model, the method comprising:
receiving natural language input associated with one or more updates to a current design problem that defines one or more associations between a plurality of interdependent design variables and geometry for a three-dimensional (3D) shape;
sending the natural language input to the language model for processing;
receiving, from the language model, a design problem that includes the one or more updates to the current design problem; and
iteratively performing, based on the design problem, one or more operations on the plurality of interdependent design variables and the geometry for the 3D shape to generate an updated geometry for the 3D shape.

2. The method of claim 1, wherein the language model is conditioned based on context data that includes data representing the current design problem.

3. The method of claim 1, wherein sending the natural language input to the language model comprises generating an embedding of at least one portion of the current design problem.

4. The method of claim 1, wherein sending the natural language input to the language model comprises generating a prompt based on the natural language input and the current design problem.

5. The method of claim 1, wherein the language model is a large language model.

6. The method of claim 1, further comprising validating the design problem that includes the one or more updates to the current design problem.

7. The method of claim 1, wherein the natural language input is received via the natural language interface.

8. The method of claim 1, wherein a physics solver iteratively performs the one or more operations on the plurality of interdependent design variables and the geometry for the 3D shape.

9. The method of claim 1, wherein each interdependent design variable included in the plurality of the interdependent design variables is associated with at least one of:
a type of physics affecting at a least one portion of the 3D shape;
an environment affecting at least one portion of the 3D shape; or
a system modeling component affecting at least one portion of the 3D shape.

10. The method of claim 1, wherein at least one interdependent design variable of the plurality of interdependent design variables is interdependent with at least one other interdependent design variable of the plurality of interdependent design variables.

11. One or more non-transitory computer-readable media including instructions that, when executed by one or more processors, cause the one or more processors to generate optimized designs using a natural language interface coupled to language model by performing the steps of:
receiving natural language input associated with one or more updates to a current design problem that defines one or more associations between a plurality of interdependent design variables and geometry for a three-dimensional (3D) shape;
sending the natural language input to the language model for processing;
receiving, from the language model, a design problem that includes the one or more updates to the current design problem; and
iteratively performing, based on the design problem, one or more operations on the plurality of interdependent design variables and the geometry for the 3D shape to generate an updated geometry for the 3D shape.

12. The one or more non-transitory computer-readable media of claim 11, wherein the language model is conditioned based on context data that includes data representing the current design problem.

13. The one or more non-transitory computer-readable media of claim 11, wherein sending the natural language input to the language model further comprises generating an embedding of at least one portion of the current design problem.

14. The one or more non-transitory computer-readable media of claim 11, wherein sending the natural language input to the language model comprises generating a prompt based on the natural language input and the current design problem.

15. The one or more non-transitory computer-readable media of claim 11, wherein the language model is a large language model.

16. The one or more non-transitory computer-readable media of claim 11, further comprising validating the design problem that includes the one or more updates to the current design problem.

17. The one or more non-transitory computer-readable media of claim 11, further comprising validating, based on a predefined schema, the design problem that includes the one or more updates to the current design problem.

18. The one or more non-transitory computer-readable media of claim 11, wherein the updated geometry for the 3D shape meets one or more constraints associated with the design problem and either maximizes or minimizes an objective function associated with the design problem.

19. The one or more non-transitory computer-readable media of claim 11, wherein receiving the natural language input further comprises receiving natural language input that indicates a request to optimize the 3D shape.

20. A system comprising:
one or more memories storing instructions; and
one or more processors coupled to the one or more memories that, when executing the instructions, perform the steps of:
receiving natural language input associated with one or more updates to a current design problem that defines one or more associations between a plurality of interdependent design variables and geometry for a three-dimensional (3D) shape;
sending the natural language input to the language model for processing;
receiving, from the language model, a design problem that includes the one or more updates to the current design problem; and
iteratively performing, based on the design problem, one or more operations on the plurality of interdependent design variables and the geometry for the 3D shape to generate an updated geometry for the 3D shape.
